(19) United States
(12) Patent Application Publication
(10) Pub. No.: US 2025/0084305 A1
(43) Pub. Date: Mar. 13, 2025

(54) QUANTUM DOT AND ELECTROLUMINESCENT ELEMENT

(71) Applicants: SHARP KABUSHIKI KAISHA, Sakai City, Osaka (JP); TOPPAN INC., Tokyo (JP)

(72) Inventors: TADASHI KOBASHI, Sakai City, Osaka (JP); HIROHISA YAMADA, Sakai City, Osaka (JP); TAKAHIRO DOE, Sakai City, Osaka (JP); Keisuke KITANO, Sakai City, Osaka (JP); Masaki YAMAMOTO, Sakai City, Osaka (JP); Yuko OGURA, Chikushino-city, Fukuoka (JP); Masanori TANAKA, Chikushino-city, Fukuoka (JP); Mikihiro TAKASAKI, Chikushino-city, Fukuoka (JP); Yuka TAKAMIZUMA, Chikushino-city, Fukuoka (JP); Soichiro NIKATA, Chikushino-city, Fukuoka (JP); Tetsuji ITO, Chikushino-city, Fukuoka (JP); Mayuko WATANABE, Chikushino-city, Fukuoka (JP)

(21) Appl. No.: 18/273,977

(22) PCT Filed: Jan. 28, 2021
(86) PCT No.: PCT/JP2021/003073

§ 371 Date: Jul. 25, 2023

(51) Int. Cl. C09K 11/08; H10K 50/115; H10K 50/16

(52) U.S. Cl. CPC C09K 11/0811; H10K 50/115; H10K 50/16

(57) ABSTRACT

A QD is a Cd-free quantum dot including a core and a shell and configured to emit blue light. The core at least contains Zn and Se. The shell has a film thickness in a range from 0.5 nm to 3 nm, contains Zn, Se, and S in a boundary portion adjacent to the core, and contains Zn and S in an outermost portion.

### TECHNICAL FIELD

The disclosure relates to a cadmium-free quantum dot and an electroluminescent element including the cadmium-free quantum dot.

### BACKGROUND ART

In recent years, various techniques related to electroluminescent elements including quantum dots have been developed. An example of such electroluminescent element is a quantum dot light-emitting diode (QLED).

Quantum dots containing cadmium (Cd) are commonly used as the quantum dots. However, Cd is internationally regulated due to its negative impact on the environment, and thus barriers for practical use are high. Therefore, in recent years, the development of Cd-free quantum dots that do not use Cd has also been examined. For example, the development of quantum dots based on chalcopyrite such as copper sulfide indium (CuInS₂), silver sulfide indium (AgInS₂) and the like, quantum dots based on indium phosphide (InP), and the like is advancing (for example, see PTL 1).

### CITATION LIST

### Patent Literature

PTL 1: WO 2007/060889

### SUMMARY OF INVENTION

### Technical Problem

However, conventionally known Cd-free quantum dots are not suitable as blue light-emitting quantum dots. External quantum efficiency (EQE) of an electroluminescent element in which Cd-free quantum dots are used is lower than the external quantum efficiency of an electroluminescent element in which Cd-containing quantum dots are used. In particular, the external quantum efficiency of an electroluminescent element in which Cd-free quantum dots that emit blue light are used is significantly lower than the external quantum efficiency of an electroluminescent element in which Cd-containing quantum dots are used.

There exists voltage dependency in a light emission peak wavelength of the quantum dot. When the light emission peak wavelength of the quantum dot is shifted by an operation voltage required for operating the electroluminescent element, color reproducibility is lost.

An aspect of the disclosure has been contrived in light of the above-mentioned problems, and an object thereof is to provide a blue light-emitting Cd-free quantum dot capable of achieving an electroluminescent element having a small variation in a light emission peak wavelength when an operation voltage is applied, excellent in color reproducibility, and having high external quantum efficiency.

Another object of an aspect of the disclosure is to provide an electroluminescent element that includes the above-mentioned quantum dot, has a small variation in a light emission peak wavelength when an operation voltage is applied, has excellent color reproducibility, and has high external quantum efficiency.

### Solution to Problem

In order to solve the above problems, a quantum dot according to an aspect of the disclosure is a Cd-free quantum dot configured to emit blue light, and including a core and a shell provided on a surface of the core. The core at least contains Zn and Se. The shell has a film thickness in a range from 0.5 nm to 3 nm, contains Zn, Se, and S in a boundary portion adjacent to the core, and contains Zn and S in an outermost portion.

In order to solve the above problems, a quantum dot according to an aspect of the disclosure is a Cd-free quantum dot configured to emit blue light, including a core and a shell covering the core, and used in an electroluminescent element for a display device. The core at least contains Zn and Se. A film thickness of the shell falls within a range from 0.5 nm to 3 nm. In a case where an operation voltage of the electroluminescent element at a luminance of 5 cd/m² is taken as Vmin, when a maximum operation voltage set as the electroluminescent element is lower than 8 V, the maximum operation voltage is taken as Vmax, and when the maximum operation voltage is higher than or equal to 8 V, 8 V is taken as Vmax, a variation in a light emission peak wavelength is smaller than or equal to 1 nm at the operation voltage in a range from the Vmin to the Vmax.

In order to solve the above problems, an electroluminescent element according to an aspect of the disclosure includes an anode electrode, a cathode electrode, and a light-emitting layer provided between the anode electrode and the cathode electrode. The light-emitting layer is a quantum dot light-emitting layer including the quantum dot according to the aspect of the disclosure.

### Advantageous Effects of Invention

According to an aspect of the disclosure, there may be provided a blue light-emitting Cd-free quantum dot capable of achieving an electroluminescent element having a small variation in a light emission peak wavelength when an operation voltage is applied, excellent in color reproducibility, and having high external quantum efficiency. Further, according to an aspect of the disclosure, there may be provided an electroluminescent element including the above-mentioned quantum dot, having a small variation in a light emission peak wavelength when an operation voltage is applied, having excellent color reproducibility, and having high external quantum efficiency.

### BRIEF DESCRIPTION OF DRAWINGS

FIG. 1 is a cross-sectional view schematically illustrating an overall configuration of an electroluminescent element according to a first embodiment.

FIG. 2 is a schematic view illustrating an example of a QD according to the first embodiment.

FIG. 3 is a graph showing a relationship between an operation voltage and a variation in a light emission peak wavelength of an electroluminescent element manufactured in Example 1.

FIG. 4 is a graph showing a relationship between an operation voltage and a variation in a light emission peak wavelength of an electroluminescent element manufactured in Example 2.

FIG. 5 is a graph showing a relationship between an operation voltage and a variation in a light emission peak wavelength of an electroluminescent element manufactured in Example 3.

FIG. 6 is a graph showing a relationship between an operation voltage and a variation in a light emission peak wavelength of an electroluminescent element for comparison manufactured in a comparative example.

FIG. 7 is a schematic view illustrating another example of a QD according to the first embodiment.

FIG. 8 is a cross-sectional view schematically illustrating an overall configuration of main portions of a display device according to a second embodiment.

FIG. 9 is a diagram for explaining a modified example of a display device according to the second embodiment.

FIG. 10 is a diagram for explaining another modified example of a display device according to the second embodiment.

FIG. 11 is a diagram for explaining a display device according to a third embodiment.

FIG. 12 is a diagram for explaining a modified example of a display device according to the third embodiment.

### DESCRIPTION OF EMBODIMENTS

### First Embodiment

An electroluminescent element (hereinafter, simply referred to as a “light-emitting element”) according to the present embodiment will be described as follows. Note that the description “A to B” for two numerals A and B is intended to mean “equal to or greater than A and equal to or less than B”, unless otherwise specified.

### Structure Example of Light-Emitting Element

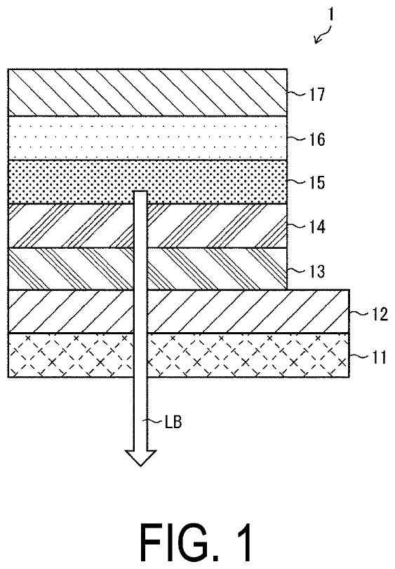

FIG. 1 is a cross-sectional view schematically illustrating an overall configuration of a light-emitting element 1 according to the present embodiment.

The light-emitting element 1 illustrated in FIG. 1 emits light when a voltage is applied to a quantum dot (also referred to as a semiconductor nanoparticle). Examples of the quantum dot include a quantum dot phosphor particle. Examples of the light-emitting element 1 include a quantum dot light emitting diode (QLED). Hereinafter, the quantum dot is abbreviated as “QD”. In the present embodiment, the QD included in the light-emitting element 1 is a blue QD.

The light-emitting element 1 includes an anode electrode 12 (anode, first electrode), a cathode electrode 17 (cathode, second electrode), and a function layer provided between the anode electrode 12 and the cathode electrode 17. The function layer includes at least a QD layer 15 (quantum dot light-emitting layer, blue quantum dot light-emitting layer) containing the QD. Note that in the present embodiment, the layers between the anode electrode 12 and the cathode electrode 17 are collectively referred to as a function layer.

The function layer may be a single layer type formed only of the QD layer 15, or may be a multi-layer type including a function layer in addition to the QD layer 15. Of the function layer, examples of function layers besides the QD layer 15 include a hole injection layer 13 (HIL), a hole transport layer 14 (HTL), and an electron transport layer 16 (ETL).

Note that in the disclosure, a direction from the anode electrode 12 to the cathode electrode 17 in FIG. 1 is referred to as an upward direction, and the opposite direction thereof is referred to as a downward direction. In the disclosure, a horizontal direction is a direction perpendicular to a vertical direction (a principal surface direction of each portion included in the light-emitting element 1). The vertical direction can also be referred to as a normal direction of each portion described above.

Each of the layers from the anode electrode 12 to the cathode electrode 17 is generally formed on a substrate used as a support body. Accordingly, the light-emitting element 1 may be provided with a substrate as a support body.

As an example, the light-emitting element 1 illustrated in FIG. 1 has a configuration in which a substrate 11, the anode electrode 12, the hole injection layer 13, the hole transport layer 14, the QD layer 15, the electron transport layer 16, and the cathode electrode 17 are layered in that order in the upward direction in FIG. 1.

However, the configuration of the light-emitting element 1 is not limited to the above configuration, and may have a configuration in which the cathode electrode 17, the electron transport layer 16, the QD layer 15, the hole transport layer 14, the hole injection layer 13, and the anode electrode 12 are layered in that order on the substrate 11.

Thus, the QD layer 15 is interposed between the anode electrode 12 and the cathode electrode 17. In other words, the anode electrode 12 and the cathode electrode 17 are provided to sandwich the QD layer 15. The light-emitting element 1 may further include an electron injection layer between the QD layer 15 and the cathode electrode 17. For example, when the light-emitting element 1 includes the electron transport layer 16 as illustrated in FIG. 1, the light-emitting element 1 may include an electron injection layer between the electron transport layer 16 and the cathode electrode 17.

Hereinafter, each layer described above will be described in greater detail.

The substrate 11 is a support body for forming each layer from the anode electrode 12 to the cathode electrode 17, as described above. As illustrated in FIG. 1, the substrate 11 supports, thereon or thereabove, the anode electrode 12, the hole injection layer 13, the hole transport layer 14, the QD layer 15, the electron transport layer 16, and the cathode electrode 17.

The substrate 11 may be, for example, a glass substrate, or may be a flexible substrate such as a plastic substrate.

The light-emitting element 1 may be used, for example, as a light source of an electronic device such as a display device. When the light-emitting element 1 is part of a display device, for example, a substrate of the display device is used as the substrate 11. Accordingly, the light-emitting element 1 may be referred to as the light-emitting element 1 including the substrate 11, or may be referred to as the light-emitting element 1 without including the substrate 11.

In this manner, the light-emitting element 1 may itself include the substrate 11, or the substrate 11 included in the light-emitting element 1 may be a substrate of an electronic device such as a display device including the light-emitting element 1. When the light-emitting element 1 is part of a display device, for example, an array substrate on which a plurality of thin film transistors are formed may be used as the substrate 11. In this case, the anode electrode 12, which is a first electrode provided on the substrate 11, may be electrically connected to the thin film transistors of the array substrate.

In the case where the light-emitting element 1 is, for example, part of a display device as discussed above, the light-emitting element 1 is provided as a light source for each pixel on the substrate 11. Specifically, a red pixel (R pixel) is provided with, as a red light source, a light-emitting element (red light-emitting element) that emits red light. A green pixel (G pixel) is provided with, as a green light source, a light-emitting element (green light-emitting element) that emits green light. A blue pixel (B pixel) is provided with, as a blue light source, a light-emitting element (blue light-emitting element) that emits blue light. Accordingly, a bank for partitioning each pixel may be formed as a pixel separation film such that a light-emitting element can be formed for each of the R pixel, G pixel, and B pixel on the substrate 11.

In the present embodiment, as described above, a case is described in which the light-emitting element 1 illustrated in FIG. 1 is a blue light-emitting element where the QD layer 15 including a blue QD is used. Note that, however, the above-mentioned red light-emitting element may be achieved by providing, as the QD layer 15, a QD layer including a red QD. Likewise, the above-mentioned green light-emitting element may be achieved by providing a QD layer including a green QD as the QD layer 15.

In a bottom-emitting (BE) type light-emitting element, light emitted from the QD layer 15 is directed downward (that is, toward the substrate 11 side). In a top-emitting (TE) type light-emitting element, light emitted from the QD layer 15 is directed upward (that is, toward the side opposite the substrate 11). In a double-sided type light-emitting element, light emitted from the QD layer 15 is directed downward and upward.

In a case where the light-emitting element 1 is a bottom-emitting (BE) type light-emitting element or a double-sided type light-emitting element, the substrate 11 is constituted by a light-transmissive substrate made of a light-transmissive material. In a case where the light-emitting element 1 is a top-emitting (TE) type light-emitting element, the substrate 11 may be constituted of a light-transmissive material, or may be constituted of a light-reflective material.

Of the anode electrode 12 and the cathode electrode 17, an electrode serving as a light extraction surface side must be light-transmissive. Note that an electrode of the side opposite the light extraction surface may or may not be light-transmissive.

For example, when the light-emitting element 1 is a BE type light-emitting element, an electrode on the upper-layer side is a light-reflective electrode, and an electrode on the lower-layer side is a light-transmissive electrode. When the light-emitting element 1 is a TE type light-emitting element, the electrode on the upper-layer side is a light-transmissive electrode, and the electrode on the lower-layer side is a light-reflective electrode. Note that the light-reflective electrode may be a layered body of a layer formed of a light-transmissive material and a layer formed of a light-reflective material.

In FIG. 1, as an example, a case is illustrated in which the light-emitting element 1 is a BE type light-emitting element where the anode electrode 12 is used as the electrode on the lower-layer side, the cathode electrode 17 is used as the electrode on the upper-layer side, and blue light LB emitted from the QD layer 15 is directed downward. Therefore, a light-transmissive electrode is used as the anode electrode 12 such that the blue light LB emitted from the QD layer 15 can be transmitted through the anode electrode 12. A light-reflective electrode is used as the cathode electrode 17 such that the blue light LB emitted from the QD layer 15 is reflected. Note that in the following description, the “blue light LB” is also abbreviated simply as “LB”. Other members will be similarly abbreviated as appropriate.

The anode electrode 12 is an electrode that supplies positive holes (holes) to the QD layer 15 when a voltage is applied. The anode electrode 12 includes, for example, a material having a relatively large work function. Examples of the material include tin-doped indium oxide (ITO), zinc-doped indium oxide (IZO), aluminum-doped zinc oxide (AZO), gallium-doped zinc oxide (GZO), and antimony-doped tin oxide (ATO). A single type of these materials may be used alone, or two or more types may be mixed and used, as appropriate.

The cathode electrode 17 is an electrode that supplies electrons to the QD layer 15 when a voltage is applied. The cathode electrode 17 includes, for example, a material having a relatively small work function. Examples of the material include aluminum (Al), silver (Ag), barium (Ba), ytterbium (Yb), calcium (Ca), lithium (Li)—Al alloys, magnesium (Mg)—Al alloys, Mg—Ag alloys, Mg-indium (In) alloys, and Al-aluminum oxide (Al₂O₃) alloys.

Film formation of the anode electrode 12 and the cathode electrode 17 may be carried out using, for example, physical vapor deposition (PVD) such as sputtering, vacuum vapor deposition or the like, spin coating, or an ink-jet method.

The hole injection layer 13 is a layer that transports positive holes supplied from the anode electrode 12, to the hole transport layer 14. The hole injection layer 13 may be formed of an organic material or may be formed of an inorganic material. An example of the organic material is an electrically conductive polymer material. As the polymer material, for example, poly(3,4-ethylenedioxythiophene) (PEDOT), or a composite (PEDOT:PSS) of poly(3,4-ethylenedioxythiophene) (PEDOT) and polystyrene sulfonic acid (PSS) can be used.

The hole transport layer 14 is a layer that transports positive holes supplied from the hole injection layer 13, to the QD layer 15. The hole transport layer 14 may be formed of an organic material or may be formed of an inorganic material. An example of the organic material is an electrically conductive polymer material. As the polymer material, for example, poly[(9,9-dioctylfluorenyl-2,7-diyl)-co-(4,4′-(N-(4-sec-butylphenyl) diphenylamine))] (TFB), poly (N-vinylcarbazole) (PVK) and the like can be used. A single type of these polymer materials may be used alone, or two or more types may be mixed and used, as appropriate. Among these polymer materials, when PVK is used, even higher EQE may be obtained. Therefore, PVK is preferably used as the polymer material described above. The hole transport layer 14 is preferably formed to have a layer thickness in a range from 5 nm to 50 nm. This allows even higher EQE to be obtained.

In the film formation of the hole injection layer 13 and the hole transport layer 14, for example, PVD such as sputtering, vacuum vapor deposition or the like, spin coating, or an ink-jet method is used. Note that in a case where positive holes can be sufficiently supplied to the QD layer 15 only by the hole transport layer 14, the hole injection layer 13 need not be provided.

The electron transport layer 16 is a layer that transports electrons supplied from the cathode electrode 17, to the QD layer 15. The electron transport layer 16 may be formed of an organic material or may be formed of an inorganic material. When the electron transport layer 16 is formed of an inorganic material, the electron transport layer 16 may contain, as the inorganic material, a metal oxide containing at least one element selected from the group consisting of zinc (Zn), magnesium (Mg), titanium (Ti), silicon (Si), tin (Sn), tungsten (W), tantalum (Ta), barium (Ba), zirconium (Zr), aluminum (Al), yttrium (Y), and hafnium (Hf). Examples of such metal oxides include zinc oxide (ZnO) and zinc magnesium oxide (ZnMgO). A single type of these metal oxides may be used alone, or two or more types may be mixed and used, as appropriate. Nanoparticles may be used in the inorganic material. The electron transport layer 16 preferably contains, among the above-mentioned inorganic materials, ZnO as indicated in Examples 1 to 3 described below. This makes it possible to provide the light-emitting element 1 capable of obtaining even higher external quantum efficiency (EQE). When the electron transport layer 16 is made of an inorganic material, PVD such as sputtering, vacuum vapor deposition or the like, spin coating, or an ink-jet method, for example, may be used for the film formation of the electron transport layer 16.

If the electron transport layer 16 is formed of an organic material, the electron transport layer 16 preferably contains, as the organic material, at least one type of compound selected from the group consisting of (i) 1,3,5-tris(1-phenyl-1H-benzimidazole-2-yl)benzene (TPBi), (ii) 3-(biphenyl-4-yl)-5-(4-tert-butylphenyl)-4-phenyl-4H-1,2,4-triazole (TAZ), (iii) bathophenanthroline (Bphen), and (iv) tris(2,4,6-trimethyl-3-(pyridine-3-yl)phenyl) borane (3TPYMB). When the electron transport layer 16 is formed of an organic material, vacuum vapor deposition, spin coating, or an ink-jet method may be used for the film formation of the electron transport layer 16.

The QD layer 15 is a light-emitting layer including QDs (QD light-emitting layer) provided between the anode electrode 12 and the cathode electrode 17.

The QD emits LB accompanying the recombination of positive holes supplied from the anode electrode 12 and electrons (free electrons) supplied from the cathode electrode 17. That is, the QD layer 15 emits light through electroluminescence (EL). More specifically, the QD layer 15 emits light through injection type EL.

The QD includes a core and a shell provided on a surface of the core. Preferably, the QD has a core-shell structure (core/shell structure) including a core and a shell covering at least part of the surface of the core. It is particularly desirable for the shell to cover the entire core. When it is found that the shell wraps the core by observing a cross section of the QD, the QD can be said to have a core-shell structure. For example, an average value of diameters corresponding to areas of circles equivalent to areas of QD cross sections (an assumed dot diameter) is calculated from the cross-section observation of 50 adjacent QDs. At this time, when a difference between the assumed dot diameter and an assumed core diameter is 0.3 nm or more, it can be said that the shell wraps the core (covers the entire core). The cross-section observation may be performed using, for example, a scanning transmission electron microscope (STEM).

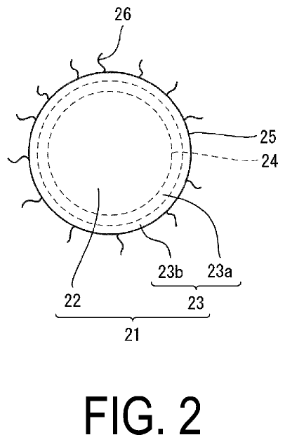

FIG. 2 is a schematic view illustrating an example of a QD 21 according to the present embodiment.

The QD 21 illustrated in FIG. 2 has a core-shell structure including a core 22 and a shell 23 covering a surface of the core 22. The shell 23 preferably has a layered structure in which a plurality of layers is layered. As an example, FIG. 2 illustrates a case in which the shell 23 has a dual-layer structure of an innermost layer 23a and an outermost layer 23b.

Numerous ligands 26 are coordinated (adsorbed) on the surface of the QD 21 illustrated in FIG. 2. The ligand 26 is a surface modifying group (ligand) that modifies the surface of the QD 21. The QD layer 15 formed by a solvolysis method contains the spherical-shaped QDs 21 and the ligands 26. By coordinating the ligands 26 on the surfaces of the QDs 21, aggregation of the QDs 21 may be suppressed, and thus the intended optical characteristics are easily exhibited.

The shell 23 may be formed in a solid solution state on the surface of the core 22. In FIG. 2, the boundary between the core 22 and the shell 23 is indicated by a dotted line, which indicates that it does not matter whether the boundary between the core 22 and the shell 23 is confirmed or not confirmed by analysis.

Likewise, in FIG. 2, the boundary between the innermost layer 23a and the outermost layer 23b is indicated by a dotted line, which indicates that it does not matter whether the boundary between the innermost layer 23a and the outermost layer 23b is confirmed or not confirmed by analysis.

The QD 21 according to the present embodiment is a nanocrystal containing no cadmium (Cd). In the disclosure, the term “nanocrystal” indicates a nanoparticle having an approximate particle size of from several nm to several tens of nm.

As the QD 21, a Cd-free QD having a core at least containing zinc (Zn) and selenium (Se) and containing no cadmium (Cd) is used. In the disclosure, “containing no Cd” or “Cd-free” means that neither the core 22 nor the shell 23 contains Cd at a mass ratio of 1/30 or more in relation to Zn.

The QD 21 is preferably a nanocrystal containing Zn and Se; Zn, Se and sulfur (S); Zn, Se and tellurium (Te); or Zn, Se, Te and S. Specifically, a ZnSe-based, ZnSeS-based, ZnSeTe-based, or ZnSeTeS-based QD is used as the QD 21.

The core 22 is formed of, for example, ZnSe, ZnSeS, ZnSeTe, or ZnSeTeS. Among these exemplary materials, the material of the core 22 is preferably ZnSe or ZnSeS, and is more preferably ZnSe.

The shell 23 contains Zn, Se, and S in a boundary portion 24 adjacent to the core 22, and contains Zn and S in an outermost portion 25 of the surface of the shell 23.

In general, there exists voltage dependency in the light emission peak wavelength of a QD. The light emission peak wavelength of the QD is shifted by the operation voltage. When the light emission peak wavelength of the QD is shifted by the operation voltage, the color reproducibility is lost.

Then, the inventors of the disclosure in the present application have conducted intensive studies in order to obtain a light-emitting element having a small variation in the light emission peak wavelength when the operation voltage is applied and having excellent color reproducibility. Consequently, the inventors of the disclosure in the present application have found that the shift of the light emission peak wavelength of the light-emitting element when the applied voltage is raised is largely affected by the configuration of the shell 23.

According to the studies conducted by the inventors of the disclosure in the present application, when the core 22 at least contains Zn and Se, and the shell 23 contains Zn, Se and S in the boundary portion 24 and contains Zn and S in the outermost portion 25, an electrical field may be dispersed (distributed) in the core 22 and the shell 23. As a result, the shift of the light emission peak wavelength due to the application of the operation voltage may be suppressed.

In the present embodiment, the boundary portion 24 of the shell 23 indicates a portion of the shell 23 adjacent to the core 22, and the outermost portion 25 of the shell 23 indicates an outer surface portion of the shell 23.

Therefore, in the QD 21 illustrated in FIG. 2, the innermost layer 23a of the shell 23 adjacent to the core 22 contains Zn, Se and S, and the outermost layer 23b thereof contains Zn and S.

As described above, by providing a layer containing Zn, Se, and S (in the present embodiment, the innermost layer 23a) between the core 22 containing Zn and Se and the outermost layer 23b of the shell 23 containing Zn and S, an electrical field may be dispersed (distributed) in the core 22 and the shell 23. As a result, the shift of the light emission peak wavelength due to the application of the operation voltage may be suppressed.

According to the present embodiment, in a case where an operation voltage of the light-emitting element 1 at a luminance of 5 cd/m² or more is taken as Vmin, when a maximum operation voltage set as the light-emitting element 1 is lower than 8 V, the maximum operation voltage (that is, the maximum operation voltage set as the light-emitting element 1) is taken as Vmax, and when the maximum operation voltage is higher than or equal to 8 V, 8 V is taken as Vmax, a variation in the light emission peak wavelength is desirably smaller than or equal to 1 nm at the operation voltage in a range from the Vmin to the Vmax in the QD 21 and the light-emitting element 1. This makes it possible to provide the QD 21 and the light-emitting element 1 having excellent color reproducibility.

According to the present embodiment, the photoluminescence quantum yield may be increased by covering the core 22 formed of a nanocrystal of ZnSe, ZnSeS, ZnSeTe, ZnSeTeS, or the like with the shell 23 containing Zn, Se and S in the boundary portion 24, and Zn and S in the outermost portion 25 as described above.

However, when a difference in lattice constants (lattice mismatch) between the core 22 and the shell 23 or a difference in lattice constants (lattice mismatch) between the boundary portion 24 and the outermost portion 25 becomes large, defects are likely to occur between the core 22 and the shell 23 or between the boundary portion 24 and the outermost portion 25. Such defects lead to a decrease in the photoluminescence quantum yield.

Then, when the composition ratio of Zn:Se:S in the shell 23 is set to 1:1-x:x, it is desirable for x to satisfy a relation of 0.2≤x≤0.8 in the boundary portion 24 and satisfy a relation of x=1 in the outermost portion 25. In other words, when the composition of the shell 23 is ZnSe₁₋ₓSₓ, it is desirable for the composition of the shell 23 in the boundary portion 24 (the composition of the innermost shell of the shell 23) to be such that x satisfies a relation of 0.2≤x≤0.8 and for the composition of the shell 23 in the outermost portion 25 (the composition of the outermost shell of the shell 23) to be such that x is equal to 1.

When x is less than 0.2 or is more than 0.8 in the boundary portion 24, the lattice mismatch between the core 22 and the shell 23 or the lattice mismatch between the boundary portion 24 and the outermost portion 25 becomes large. Then, as described above, the occurrence of defects due to the lattice mismatch may be suppressed by setting x to be 0.2 or more and 0.8 or less in the boundary portion 24.

Therefore, in the QD 21 illustrated in FIG. 2, when the composition ratio of Zn:Se:S in the shell 23 is set to 1:1-x:x as described above, for example, it is desirable for x that a relation of 0.2≤x≤0.8 be satisfied in the innermost layer 23a, and a relation of x=1 be satisfied in the outermost layer 23b. This makes it possible to suppress the occurrence of defects caused by an increase in the lattice mismatch between the innermost layer 23a and the outermost layer 23b and to suppress a decrease in the photoluminescence quantum yield.

It is desirable for the composition of the shell 23 to change in such a manner that the composition ratio of Se in relation to Zn stepwisely decreases and the percentage content of S in relation to Zn stepwisely increases from the boundary portion 24 toward the outermost portion 25.

With this, the occurrence of defects due to lattice mismatch of the shell 23 may be suppressed, and the band gap of the shell 23 may be increased from the boundary portion 24 toward the outermost portion 25. This makes it possible to provide the QD 21 having a high photoluminescence quantum yield.

Accordingly, the shell 23 may have a layered structure of two or more layers, or may have a structure in which the above-discussed x gradually changes at the boundary between the innermost layer 23a and the outermost layer 23b, therefore the boundary between the innermost layer 23a and the outermost layer 23b is not clearly distinguished.

The photoluminescence quantum yield (for example, fluorescence quantum yield (QY)) of the QD 21 according to the present embodiment is 5% or more. The photoluminescence quantum yield is preferably 20% or greater, more preferably 50% or greater, and even more preferably 80% or greater. In this manner, the photoluminescence quantum yield of the QD 21 may be increased in the present embodiment.

Zn and Se, Zn, Se and S, Zn, Se and Te, or Zn, Se, Te and S included in the QD 21 are main components. The QD 21 may include elements besides these elements.

For example, in the QD 21, of the core 22 and shell 23, at least the core 22 may further contain copper (Cu) as an element. As a compound, for example, Cu₂Se or the like may be contained in at least the core 22 out of the core 22 and the shell 23.

When the QD 21 contains Cu, regardless of whether Cu is contained only in the core 22 or in both the core 22 and the shell 23, the content of Cu is preferably 0.1 ppm or more and 10 ppm or less in relation to Zn in the QD 21. In the QD 21, the content of Zn and Cu and the content of Cu in relation to Zn can be quantified by, for example, inductively coupled plasma (ICP) light emission spectrometry.

By synthesizing the QD 21 by a cation exchange method described below, the particle size can be controlled by a copper chalcogenide precursor, and the synthesis of the QD 21, which is unlikely to react by nature, is enabled. The ZnSe-based QD 21 synthesized by the cation exchange method is likely to have a higher residual amount of Cu than the ZnSe-based QD 21 synthesized by a direct method. However, as long as the content of Cu in relation to Zn falls within the above-discussed range, favorable light-emission characteristics may be obtained. The residual amount of Cu is useful when it is judged whether the cation exchange method was used. The core-shell structure may be synthesized at a stage of the copper chalcogenide precursor.

Note that, however, it is preferable for the QD 21 to contain neither Cd nor phosphorus (P). Organic phosphorus compounds are expensive. Furthermore, organic phosphorus compounds are easily oxidized in air, and therefore a variety of problems are likely to occur such as unstable synthesis, an increase in costs, unstable light-emission characteristics, an increase in the complexity of the manufacturing process and the like.

The QD 21 has light-emission characteristics by band edge emission, and a quantum size effect is exhibited because of the particle being of a nano size.

In general, in a core-shell type QD, the wavelength of light emitted by the QD is proportional to the particle size of the core and does not depend on the outermost particle size of the QD including the shell.

Because of this, although the peak wavelength dependency is present by a subtle composition ratio of constituent elements of the QD 21 and a difference in the relationship between the particle size and the degree of wavelength dependency is present depending on the particle size region, it is preferable for the particle size of the core 22 to fall within a range from 3 nm to 20 nm. The particle size of the core 22 preferably falls within a range from 5 nm to 20 nm. Moreover, the particle size of the core 22 is more preferably 15 nm or less, and is even more preferably 10 nm or less. In the present embodiment, the particle size of the core 22 may be adjusted within the range described above, and a large number of cores 22 may be produced with a substantially uniform particle size.

In the case where the QD 21 has a core-shell structure as discussed above, the particle size of the QD 21 indicates the particle size of the QD 21 in a state of being covered with the shell 23 (the outermost particle size of the QD 21). As described above, according to the present embodiment, the QD 21 of the core-shell structure with a very small uniformed particle size may be obtained.

In the present embodiment, as described above, the particle size of the QD 21 can be reduced and a variation in the particle size of each of the QDs 21 can be reduced, therefore the QD 21 having a uniformed size can be obtained.

Accordingly, in the present embodiment, the fluorescence full-width at half-maximum of the QD 21 may be narrowed to be 25 nm or less, for example, and the formation of a high color gamut may be improved. Note that the “fluorescence full-width at half-maximum” in the disclosure is a full width at half maximum (FWHM), which indicates the spread of fluorescence wavelengths at half the intensity of a peak value of a fluorescence intensity in a fluorescent spectrum.

The fluorescence full-width at half-maximum is preferably 23 nm or smaller, more preferably 20 nm or smaller, and even more preferably 15 nm or smaller. In the present embodiment, the fluorescence full-width at half-maximum can be narrowed in this manner, and thus the formation of a high color gamut can be improved.

In particular, the QD 21 according to the present embodiment is synthesized by synthesizing a copper chalcogenide as a precursor from a copper (Cu) raw material and an organic chalcogen compound (organic chalcogenide) as an Se raw material or a Te raw material, and then performing metal exchange between Cu of the copper chalcogenide and Zn. Note that an organic copper compound or an inorganic copper compound is used for the Cu raw material.

According to the present embodiment, synthesis can be safely implemented by synthesizing the QD 21 based on an indirect synthesis reaction using these types of materials having relatively high stability (materials with relatively low reactivity), and as described above, the QDs 21 having the uniform size can be obtained. As a result, the fluorescence full-width at half-maximum can be narrowed, and a fluorescence full-width at half-maximum of 25 nm or less can be achieved as described above.

According to the present embodiment, for example, the fluorescence lifetime of the QD 21 may be caused to be 50 ns or less. Note that in the disclosure, “fluorescence lifetime” indicates the “time until the initial intensity becomes 1/e (approximately 37%)”.

In addition, in the present embodiment, the fluorescence lifetime can be adjusted to 40 ns or less, and even 30 ns or less. In the present embodiment, the fluorescence lifetime can be shortened in this manner, but can also be extended to approximately 50 ns, and thus the fluorescence lifetime can be adjusted according to the usage application.

According to the present embodiment, as described above, by causing the particle size of the core 22 to fall within a range from 3 nm to 20 nm, it is possible to provide the QD 21 configured to emit blue light having a light emission peak wavelength of 410 nm to 470 nm. By causing the particle size of the core 22 to fall within the range from 3 nm to 20 nm, it is possible to provide the QD 21 capable of achieving the light-emitting element 1, in which surface irregularities are small at the time of film formation, the current injection is uniform, light emission unevenness may be suppressed, the QD 21 density in the QD layer 15 is large, and the luminous efficiency is excellent.

In a case where the particle size of the core 22 is smaller than 3 nm, it may be difficult to make the light emission peak wavelength longer than or equal to 410 nm. In a case where the particle size of the core 22 is larger than 20 nm, when the light-emitting element 1 is manufactured, surface irregularities at the time of film formation of the QD layer 15 become large, and the current injection becomes non-uniform, which may cause light emission unevenness. In addition, the density of the QDs 21 in the QD layer 15 may decrease, and the luminous efficiency may decrease.

In the present embodiment, the light emission peak wavelength (for example, fluorescent peak wavelength) may be freely controlled approximately in a range from 410 nm to 470 nm. The light emission peak wavelength of the QD 21 falls within a range from 410 nm to 470 nm. According to the present embodiment, the light emission peak wavelength may be controlled by adjusting the particle size and composition of the QD 21. The QD 21 is, for example, a ZnSe-based or ZnSeS-based solid solution in which a chalcogen element is used in addition to Zn in the core 22. In this case, the light emission peak wavelength may be preferably set in a range from 440 nm to 470 nm, and more preferably in a range from 450 nm to 470 nm. Furthermore, also in the ZnSeTe-based or ZnSeTeS-based QD 21 using ZnSeTe or ZnSeTeS in the core 22, the light emission peak wavelength may be set in a range from 450 nm to 470 nm. In this manner, the light emission peak wavelength of the QD 21 may be controlled to exhibit a blue color in the present embodiment.

According to the present embodiment, in the case where the light emission peak wavelength is equal to or longer than 440 nm and equal to or shorter than 470 nm, an electrical field shielding effect when the core 22 is covered with a film containing Zn, Se, and S (for example, ZnSeS) as the innermost layer 23a of the shell 23 adjacent to the core 22 is increased. In other words, as the particle size of the core 22 is larger, the electrical field shielding effect when the core 22 is covered with the film containing Zn, Se, and S (for example, ZnSeS) as the innermost layer 23a of the shell 23 adjacent to the core 22 is increased. This makes it possible to suppress the shift of the peak wavelength by the voltage application.

According to the present embodiment, the fluorescence lifetime may be further shortened by adopting a core-shell structure for the QD 21 in comparison with the core 22 alone having the same composition and particle size.

In comparison with the case of the core 22 alone, the fluorescent peak wavelength may be shortened or lengthened by covering the core 22 with the shell 23. For example, when the particle size of the core 22 is small, the fluorescent peak wavelength tends to be lengthened by covering the core 22 with the shell 23. On the other hand, when the particle size of the core 22 is large, the fluorescent peak wavelength tends to be shortened by covering the core 22 with the shell 23. The magnitude of a value of the wavelength change varies depending on the covering conditions by the shell 23.

The film thickness (shell thickness) of the shell 23 is one of the most important factors determining the efficiency and reliability of the light-emitting element 1 (QLED). In order to obtain better light emission performance, it is desirable for the QD 21 to have a core-shell structure. When the shell thickness is too thick, the photoluminescence quantum yield (for example, fluorescence quantum yield (QY)) is lowered.

According to the disclosure, when the film thickness of the shell 23 is equal to or less than 3 nm (that is, in a range from 0 nm to 3 nm), a fluorescent peak wavelength with a fluorescence lifetime of 50 ns or less, for example, may be obtained as a light emission peak wavelength, and a high photoluminescence quantum yield (for example, fluorescence quantum yield (QY)) may be obtained. The external quantum efficiency (%) is expressed by (carrier balancing)×(generation efficiency of luminescent excitons)×(photoluminescence quantum yield)×(light extraction efficiency) and is proportional to the photoluminescence quantum yield. Accordingly, the light-emitting element 1 capable of obtaining high external quantum efficiency (EQE) may be provided by causing the film thickness of the shell 23 to be 3 nm or less.

In this case, the film thickness of the shell 23 indicates the sum of the layer thicknesses of the respective layers (total thickness) in the shell 23. Accordingly, in the example illustrated in FIG. 2, the film thickness of the shell 23 represents the total thickness indicating the sum of the layer thicknesses of the innermost layer 23a and the outermost layer 23b.

The film thickness of the shell 23 is preferably 0.5 nm or more, more preferably 1.0 nm or more, and even more preferably 1.5 nm or more. The film thickness of the shell 23 is more preferably 2.8 nm or less, and even more preferably 2.5 nm or less.

When the film thickness of the shell 23 is less than 0.5 nm, the protection against defects existing in the core 22 may be insufficient, and thus the photoluminescence quantum yield may decrease. In a case where the light-emitting element 1 using such QD 21 is manufactured, the luminous efficiency of the light-emitting element 1 may be lowered. On the other hand, when the film thickness of the shell 23 is larger than 3.0 nm, influence of a difference in lattice constants between the core 22 and the shell 23 more noticeably appears, therefore the photoluminescence quantum yield may be lowered. A reduction in the photoluminescence quantum yield leads to a reduction in the external quantum efficiency. Further, since the film thickness of the shell 23 is large, it is difficult to inject a current into the QD 21. Due to this, in the case where the light-emitting element 1 using such QD 21 is manufactured, the luminous efficiency of the light-emitting element 1 may be lowered.

Accordingly, by causing the film thickness of the shell 23 to fall within a range from 0.5 nm to 3 nm, it is possible to provide the QD 21 capable of achieving the light-emitting element 1 able to suppress the reduction in the photoluminescence quantum yield, make the current easily injected, and have high external quantum efficiency.

In the case where the shell 23 has a dual-layer structure of the innermost layer 23a and the outermost layer 23b as described above, when a relation of (the layer thickness of the innermost layer 23a):(the layer thickness of the outermost layer 23b)=1−y:y is given, it is desirable for y to satisfy a relation of 0.2≤y≤0.8. In other words, the layer thickness of each layer of the shell 23 is desirably 20% or more of the film thickness (total thickness) of the shell 23.

The upper limit of the layer thickness of each layer of the shell 23 is determined in accordance with the number of layers of the shell 23 such that the sum total of the thicknesses of the respective layers (total thickness) of the shell 23 is 100%, and the layer thickness of each layer of the shell 23 is preferably 20% or more of the film thickness (total thickness) of the shell 23.

In any layer of the shell 23, when the layer thickness is less than 20% of the film thickness of the shell 23, there is a possibility that the function as the shell cannot be sufficiently exhibited. Therefore, the layer thickness of any layer of the shell 23 is desirably 20% or more of the film thickness of the shell 23.

Accordingly, in the example illustrated in FIG. 2, each of the innermost layer 23a and the outermost layer 23b of the shell 23 is preferably 20% or more of the film thickness of the shell 23. For this reason, when the shell 23 has a dual-layer structure of the innermost layer 23a and the outermost layer 23b as illustrated in FIG. 2, the layer thickness of the innermost layer 23a is desirably 20% or more and 80% or less of the film thickness of the shell 23.

As discussed above, in any layer of the shell 23, when the layer thickness thereof is less than 20% of the film thickness of the shell 23, there is a possibility that the function as the shell cannot be sufficiently exhibited. In this case, particularly when the layer thickness of the innermost layer 23a adjacent to the core 22 is thin, there is a possibility that a reduction in shift of the peak wavelength by the voltage application is insufficient. Therefore, the layer thickness of the innermost layer 23a is desirably 20% or more and 80% or less of the film thickness of the shell 23.

˜As illustrated in FIG. 2, it is preferable for numerous ligands 26 to be coordinated on the surface of the QD 21. With this, the aggregation of the QDs 21 may be suppressed, and the intended optical characteristics are exhibited. Furthermore, the addition of amine-based or thiol-based ligands 26 may significantly improve the stability of the light-emission characteristics of the QD 21. The ligand 26 able to be used in the reaction is not particularly limited, and examples of the ligand 26 include amine-based (aliphatic primary amine-based), fatty acid-based, thiol-based (sulfur-based), phosphine-based (phosphorus-based), and phosphine oxide-based ligands.

Examples of the aliphatic primary amine-based ligand 26 include oleylamine (C₁₈H₃₅NH₂), stearyl (octadecyl) amine (C₁₈H₃₇NH₂), dodecyl (lauryl) amine (C₁₂H₂₅NH₂), decylamine (C₁₀H₂₁NH₂), and octylamine (C₈H₁₇NH₂).

Examples of the fatty acid-based ligand 26 include oleic acid (C₁₇H₃₃COOH), stearic acid (C₁₇H₃₅COOH), palmitic acid (C₁₅H₃₁COOH), myristic acid (C₁₃H₂₇COOH), lauric (dodecanoic) acid (C₁₁H₂₃COOH), decanoic acid (C₉H₁₉COOH), and octanoic acid (C₇H₁₅COOH).

Examples of the thiol-based ligand 26 include octadecanethiol (C₁₈H₃₇SH), hexanedecanethiol (C₁₆H₃₃SH), tetradecanethiol (C₁₄H₂₉SH), dodecanethiol (C₁₂H₂₅SH), decanethiol (C₁₀H₂₁SH), and octanethiol (C₈H₁₇SH).

Examples of the phosphine-based ligand 26 include trioctylphosphine ((C₈H₁₇)₃P), triphenylphosphine ((C₆H₅)₃P), and tributyl phosphine ((C₄H₉)₃P).

Examples of the phosphine oxide-based ligand 26 include trioctylphosphine oxide ((C₈H₁₇)₃P═O), triphenylphosphine oxide ((C₆H₅)₃P═O), and tributyl phosphine oxide ((C₄H₉)₃P═O).

The QD layer 15 is preferably formed such that the layer thickness thereof is in a range from 10 nm to 60 nm, and more preferably formed such that the layer thickness thereof is in a range from 15 nm to 55 nm. This makes it possible to obtain high EQE.

A technique such as spin coating, an ink-jet method, photolithography, or the like is preferably used for the film formation of the QD layer 15.

In the light-emitting element 1, a forward voltage is applied between the anode electrode 12 and the cathode electrode 17. In other words, the anode electrode 12 is set to a higher potential than the cathode electrode 17. Through this, (i) electrons can be supplied from the cathode electrode 17 to the QD layer 15, and (ii) positive holes can be supplied from the anode electrode 12 to the QD layer 15. As a result, the QD layer 15 can generate the LB in association with the recombination of the positive holes and the electrons. The above-described application of voltage may be controlled by a thin film transistor (TFT) (not illustrated). As an example, a TFT layer including a plurality of TFTs may be formed in the substrate 11.

The light-emitting element 1 may include, as a function layer, a hole blocking layer (HBL) that suppresses the transport of positive holes. The hole blocking layer is provided between the anode electrode 12 and the QD layer 15. By providing the hole blocking layer, the balance of the carriers (i.e., positive holes and electrons) supplied to the QD layer 15 can be adjusted.

In addition, the light-emitting element 1 may include, as a function layer, an electron blocking layer (EBL) that suppresses the transport of electrons. The electron blocking layer is provided between the QD layer 15 and the cathode electrode 17. By providing the electron blocking layer, the balance of the carriers (i.e., positive holes and electrons) supplied to the QD layer 15 can also be adjusted.

The light-emitting element 1 may be sealed after the film formation as far as the cathode electrode 17 has been completed. For example, glass or a plastic can be used as a sealing member. The sealing member has, for example, a concave shape, therefore a layered body from the substrate 11 to the cathode electrode 17 can be sealed. For example, after a sealing adhesive (for example, an epoxy-based adhesive) is applied between the sealing member and the substrate 11, sealing is implemented in a nitrogen (N₂) atmosphere, and thus the light-emitting element 1 is manufactured.

### Application in Display Device

As described above, the light-emitting element 1 is applied, for example, as a blue light source of a display device. A light source including the light-emitting element 1 may include a light-emitting element as a red light source and a light-emitting element as a green light source. In this case, the light source functions as, for example, a light source for lighting an R pixel, a G pixel, and a B pixel, as indicated in a below-described second embodiment. The display device including this light source can express an image by a plurality of pixels including the R pixel, the G pixel, and the B pixel.

For example, the R pixel, the G pixel, and the B pixel are respectively formed by separately patterning each of the layers of the light-emitting element 1 including at least the QD layer 15 on the substrate 11 provided with banks. For example, indium phosphide (InP) is suitably used as the red QD and the green QD used for the R pixel and G pixel respectively, as long as the materials are limited to non-Cd-based materials. When InP is used, the fluorescence full-width at half-maximum can be made relatively narrow, and high luminous efficiency can be obtained.

Film formation of the electron transport layer 16 may be implemented with a plurality of pixel units or may be implemented in common for the plurality of pixels, provided that the display device can light up the R pixel, G pixel, and B pixel individually.

### Method for Manufacturing Light-Emitting Element

Next, an example of a method for manufacturing the light-emitting element 1 will be described. The light-emitting element 1 is manufactured, for example, by performing film formation of the anode electrode 12, the hole injection layer 13, the hole transport layer 14, the QD layer 15, the electron transport layer 16, and the cathode electrode 17 on or above the substrate 11 in that order.

Specifically, for example, the anode electrode 12 is formed on the substrate 11 by sputtering (anode electrode formation step). Next, after a solution containing, for example, PEDOT:PSS has been applied onto the anode electrode 12 by spin coating, the solvent is volatilized by baking to form the hole injection layer 13 (hole injection layer formation step). Next, after a solution containing, for example, PVK is applied onto the hole injection layer 13 by spin coating, the solvent is volatilized by baking to form the hole transport layer 14 (hole transport layer formation step). Next, the QD layer 15 is formed on the hole transport layer 14 using a solvolysis method. Specifically, after a dispersion (liquid composition) in which the QDs 21 are dispersed has been applied onto the hole transport layer 14 by spin coating, the solvent is volatilized by baking to form the QD layer 15 (light-emitting layer formation step). Next, after a solution containing, for example, nanoparticles of ZnO has been applied onto the QD layer 15 by spin coating, the solvent is volatilized by baking to form the electron transport layer 16 (electron transport layer formation step). Next, the cathode electrode 17 is formed on the electron transport layer 16 by vacuum vapor deposition (cathode electrode formation step).

The QD 21 contained in the QD layer 15 is synthesized as follows: a copper chalcogenide as a precursor is synthesized from an organic or inorganic copper compound and an organic chalcogen compound, and then the QD 21 is synthesized using the copper chalcogenide (quantum dot synthesis step). In other words, in the light-emitting layer formation step, the QD layer 15 containing the QDs 21 synthesized in this manner is formed. The quantum dot synthesis step (also referred to as the QD synthesis step) will be described later.

As described above, in the light-emitting layer formation step, the QD layer 15 is formed such that the layer thickness thereof falls within a range from 10 nm to 60 nm, and preferably from 15 nm to 55 nm.

As described above, in the hole transport layer formation step, the hole transport layer 14 is formed such that the layer thickness thereof falls within a range from 5 nm to 50 nm.

After the film formation of the cathode electrode 17, the substrate 11 and the layered body (the anode electrode 12 to the cathode electrode 17) formed on the substrate 11 may be sealed with a sealing member in an N₂ atmosphere.

### Synthesis Method of QD 21

Next, an example of a method for synthesizing the QD 21 (QD synthesis step) will be described.

In the present embodiment, first, a copper chalcogenide is synthesized as the precursor from a Cu raw material (an organic copper compound or an inorganic copper compound) and an organic chalcogen compound as an Se raw material or Te raw material. Preferable examples of the copper chalcogenide (precursor) include Cu₂Se, Cu₂SeS, Cu₂SeTe, and Cu₂SeTeS.

The organic copper compound (organic copper reagent) used as the Cu raw material is not particularly limited, and examples thereof include acetates and fatty acid salts. Furthermore, the inorganic copper compound (inorganic copper reagent) used as the Cu raw material is also not particularly limited, and examples thereof include halides (copper halides).

More specifically, examples of the acetates include copper(I) acetate (Cu(OAc)) and copper(II) acetate (Cu(OAc)₂).

Examples of the fatty acid salts include copper stearate (Cu(OC(═O)C₁₇H₃₅)₂), copper oleate (Cu(OC(═O)C₁₇H₃₃)₂), copper myristate (Cu(OC(═O)C₁₃H₂₇)₂), copper dodecanoate (Cu(OC(═O)C₁₁H₂₃)₂), and copper acetylacetonate (Cu(acac)₂).

Both monovalent and divalent compounds can be used as the halide. Examples of the halide include copper(I) chloride (CuCl), copper(II) chloride (CuCl₂), copper(I) bromide (CuBr), copper(II) bromide (CuBr₂), copper(I) iodide (CuI), and copper(II) iodide (CuI₂).

In the present embodiment, an organic selenium compound (organic chalcogen compound) is used as a raw material of Se. The organic selenium compound (organic chalcogen compound) is not particularly limited, and for example, trioctylphosphine selenide ((C₈H₁₇)₃P═Se) obtained by dissolving Se in trioctylphosphine, and tributylphosphine selenide ((C₄H₉)₃P═Se) obtained by dissolving Se in tributylphosphine can be used. Also, other examples of the organic selenium compound (organic chalcogen compound) that can be used include a solution (Se-ODE) in which Se is dissolved at a high temperature in a high boiling point solvent, which is a long chain hydrocarbon such as octadecene, and a solution (Se-DDT/OLAm) in which Se is dissolved in a mixture of oleylamine and dodecanethiol.

In the present embodiment, an organic tellurium compound (organic chalcogen compound) is used as the Te raw material. The organic tellurium compound (organic chalcogen compound) is not particularly limited, and for example, trioctylphosphine telluride ((C₈H₁₇)₃P═Te) obtained by dissolving Te in trioctylphosphine, and tributylphosphine telluride ((C₄H₉)₃P═Te) obtained by dissolving Te in tributylphosphine can be used. Also, as the organic tellurium compound (organic chalcogen compound), a dialkyl ditelluride (R₂Te₂; where R denotes a C1-C6 alkyl group), such as diphenyl ditelluride ((C₆H₅)₂Te₂), can be used.

In the synthesis of the copper chalcogenide, first, an organic copper compound or an inorganic copper compound, and an organic chalcogen compound are mixed and dissolved in a solvent.

Examples of the solvent include saturated or unsaturated hydrocarbons having a high boiling point. Examples of high boiling point saturated hydrocarbons that can be used include n-dodecane, n-hexadecane, and n-octadecane. An example of a high boiling point unsaturated hydrocarbon that can be used is octadecene. Note that, for example, an aromatic solvent having a high boiling point, and an ester-based solvent having a high boiling point may also be used as the solvent. For example, t-butyl benzene can be used as an aromatic solvent having a high boiling point. Examples of high boiling point ester-based solvents that can be used include butyl butyrate (C₄H₉COOC₄H₉) and benzyl butyrate (C₆H₅CH₂COOC₄H₉). However, aliphatic amine-based compounds, fatty acid-based compounds, aliphatic phosphorus-based compounds, or mixtures thereof can also be used as the solvent.

Next, the reaction temperature is set to within a range of from 140° C. to 250° C., and the copper chalcogenide (precursor) is synthesized. Note that the reaction temperature is preferably a lower temperature within a range of from 140° C. to 220° C., and more preferably an even lower temperature within a range of from 140° C. to 200° C. In this manner, according to the present embodiment, the copper chalcogenide can be synthesized at a low temperature, and therefore the copper chalcogenide can be safely synthesized. In addition, since the reaction during synthesis is gentle, the reaction is easier to control.

In the present embodiment, the reaction method is not particularly limited, but it is important to synthesize Cu₂Se, Cu₂SeS, Cu₂SeTe, and Cu₂SeTeS having uniform particle sizes in order to obtain the QD 21 having a narrow fluorescence full-width at half-maximum.

Also, the particle size of the copper chalcogenide (precursor) such as Cu₂Se, Cu₂SeS, Cu₂SeTe, Cu₂SeTeS and the like is preferably 20 nm or less, more preferably 15 nm or less, and even more preferably 10 nm or less. Wavelength control of the QDs 21, such as the ZnSe-based, ZnSeS-based, ZnSeTe-based, ZnSeTeS-based QDs 21 and the like, is enabled depending on the composition and particle size of the above-mentioned copper chalcogenide. Therefore, it is important to appropriately control the particle size.

It is important to cause S to be subjected to solid solution treatment in the core in order to obtain the QD 21 with a narrower fluorescence full-width at half-maximum. For this reason, thiol is preferably added in the synthesis of, for example, Cu₂Se or Cu₂SeTe as the precursor. The above-described Se-DDT/OLAm is more preferably used as the Se raw material in order to obtain the QD 21 having a narrower fluorescence full-width at half-maximum.

While the thiol is not particularly limited, examples of thiols that can be used include octadecanethiol (C₁₈H₃₇SH), hexanedecanethiol (C₁₆H₃₃SH), tetradecanethiol (C₁₄H₂₉SH), dodecanethiol (C₁₂H₂₅SH), decanethiol (C₁₀H₂₁SH), and octanethiol (C₈H₁₇SH).

Next, an organic zinc compound or an inorganic zinc compound is prepared as a Zn raw material of ZnSe, ZnSeS, ZnSeTe or ZnSeTeS. The organic zinc compound or the inorganic zinc compound is a raw material that is stable even in air and easy to handle. The organic zinc compound or the inorganic zinc compound is not particularly limited, but a zinc compound with high ionic properties is preferably used in order to efficiently carry out a metal exchange reaction. Examples of the organic zinc compound include acetates, nitrates and fatty acid salts. Examples of the inorganic zinc compound include halides (zinc halides).

An example of the acetate that can be used is zinc acetate (Zn(OAc)₂). An example of the nitrate that can be used is zinc nitrate (Zn(NO₃)₂).

More specifically, examples of fatty acid salts that can be used include zinc stearate (Zn(OC(═O)C₁₇H₃₅)₂), zinc oleate (Zn(OC(═O)C₁₇H₃₃)₂), zinc palmitate (Zn(OC(═O)C₁₅H₃₁)₂), zinc myristate (Zn(OC(═O)C₁₃H₂₇)₂), zinc dodecanoate (Zn(OC(═O)C₁₁H₂₃)₂), and zinc acetylacetonate (Zn(acac)₂).

Note that the organic zinc compound may be a zinc carbamate. Examples of zinc carbamates that can be used include zinc diethyldithiocarbamate (Zn(SC(═S)N(C₂H₅)₂)₂), zinc dimethyldithiocarbamate (Zn(SC(═S)N(CH₃)₂)₂), and zinc dibutyldithiocarbamate (Zn(SC(═S)N(C₄H₉)₂)₂).

Examples of halides that can be used include zinc chloride (ZnCl₂), zinc bromide (ZnBr₂), and zinc iodide (ZnI₂).

Subsequently, the above-described organic zinc compound or inorganic zinc compound is added to the reaction solution in which the copper chalcogenide (precursor) was synthesized. This results in a metal exchange reaction between Cu of the copper chalcogenide and Zn. The metal exchange reaction is preferably carried out at a temperature of 150° C. or more and 300° C. or less. Further, the metal exchange reaction is more preferably carried out at a lower temperature in a range of from 150° C. to 280°, and is even more preferably carried out at a temperature in a range of from 150° C. to 250° C. In this manner, in the present embodiment, the metal exchange reaction can be carried out at a lower temperature, and therefore the safety of the metal exchange reaction can be increased. Furthermore, the metal exchange reaction is more easily controlled.

In the present embodiment, preferably, the metal exchange reaction between Cu and Zn proceeds quantitatively, and the nanocrystals do not contain Cu of the precursor. This is because when Cu of the copper chalcogenide remains in the nanocrystals, Cu serves as a dopant, light is emitted by another light emission mechanism, and the fluorescence full-width at half-maximum may be widened. The residual amount of this Cu is preferably 100 ppm or less, more preferably 50 ppm or less, and ideally 10 ppm or less, in relation to the Zn.

The ZnSe-based QD 21 synthesized by the cation exchange method is likely to have a higher residual amount of Cu than the ZnSe-based QD 21 synthesized by the direct method. However, basically, Cu can be completely replaced to lower the concentration of Cu to almost 0. The lower the concentration of Cu is, the more the characteristics as the QD 21 may be improved. However, as long as Cu is used as a raw material, there is a possibility that Cu remains depending on conditions.

According to the present embodiment, even in a case where Cu is contained approximately in an amount of 0.1 ppm to 10 ppm, for example, in relation to Zn, favorable light-emission characteristics may be obtained. As described above, the residual amount of Cu makes it possible to judge whether the QD 21 was synthesized by the cation exchange method. That is, synthesis by the cation exchange method enables control of the particle size with the copper chalcogenide, and also enables the synthesis of the QD 21, which is unlikely to react by nature. Therefore, the residual amount of Cu can be used for determining whether the cation exchange method was used.

In the present embodiment, a compound having an auxiliary role of releasing the metal of the copper chalcogenide into the reaction solution by coordination, chelating, or the like is required when metal exchange is carried out.

An example of the compound having the above-described role is a ligand (surface modifier) capable of forming a complex with Cu. As this ligand, for example, a ligand similar to the ligands given as examples above can be used. Preferable examples of the ligand include the above-described phosphine-based (phosphorus-based) ligands, amine-based ligands, and thiol-based (sulfur-based) ligands. Among these, in consideration of the level of the reaction efficiency to be high, a phosphine-based (phosphorus-based) ligand is more preferable. Through the use of such ligands, the metal exchange between Cu and Zn is appropriately implemented, and the QD 21 having a narrow fluorescence full-width at half-maximum and being based on Zn and Se may be manufactured. In the present embodiment, the QD 21 may be mass-produced by the above-described cation exchange method more appropriately than the direct synthesis method.

That is, in the direct synthesis method, for example, an organic zinc compound such as diethylzinc (Et₂Zn) is used for increasing the reactivity of Zn raw material. However, diethylzinc is highly reactive and ignites in air, and therefore raw material handling and storage are difficult. For example, the material needs to handle in an inert gas stream. A reaction using diethylzinc also carries risks such as exotherm, ignition and the like, and therefore diethylzinc is not suited for mass production. Likewise, reactions in which, for example, hydrogen selenide (H₂Se) is used for increasing the reactivity of the Se raw material are also not suited for mass production from the perspectives of toxicity and safety.

In addition, in reaction systems using the Zn raw material and the Se raw material with high reactivity as described above, ZnSe is produced, but particle production is not controlled, and as a result, the fluorescence full-width at half-maximum of the produced ZnSe becomes wider.

In contrast, as described above, in the present embodiment, the copper chalcogenide is synthesized as the precursor from an organic copper compound or an inorganic copper compound and an organic chalcogen compound. Then, the QD 21 is synthesized by performing metal exchange using the precursor. Thus, in the present embodiment, the QD 21 is synthesized through the synthesis of the precursor, and the QD 21 is not synthesized directly from the raw material. According to the present embodiment, through this type of indirect synthesis, it is unnecessary to use dangerous reagents that are highly reactive and difficult to handle, therefore the ZnSe-based QD 21 having a narrow fluorescence full-width at half-maximum may be safely and stably synthesized.

Furthermore, in the present embodiment, it is also not always necessary to isolate and purify the precursor. Because of this, for example, the desired QD 21 may be obtained by performing metal exchange between Cu and Zn in one pot. However, the copper chalcogenide as the precursor may be isolated and purified prior to the synthesis of the QD 21, and then used.

The QD 21 synthesized by the above-described technique may exhibit predetermined fluorescence characteristics without performing various treatments such as cleaning, isolation and purification, covering treatment, ligand exchange and the like.

However, as described above, the fluorescence quantum yield may be further increased by covering the core 22 made of a nanocrystal such as ZnSe, ZnSeS, ZnSeTe, or ZnSeTeS, with the shell 23 made of ZnS, ZnSeS, or the like. Furthermore, adopting the core-shell structure allows the fluorescence lifetime to be shortened in comparison with prior to covering with a shell.

As described above, in comparison with a case of the core 22 alone, the fluorescent peak wavelength can be shortened or lengthened by adopting the core-shell structure.

In addition, by adding, to the core 22 made of a nanocrystal such as ZnSe, ZnSeS, ZnSeTe, ZnSeTeS or the like obtained by the cation exchange method, ZnSe, ZnSeS, ZnSeTe or ZnSeTeS being the same material as above, the core 22 of the QD 21 changed to have an optional particle size while maintaining the particle size uniform may be obtained. Therefore, the wavelength is easily controlled to a range of from 410 nm to 470 nm while maintaining the fluorescence full-width at half-maximum at 25 nm or less.

According to the present embodiment, the core-shell structure (core/shell structure) can be formed at the stage of synthesizing the precursor. For example, as the precursor, a precursor (copper chalcogenide) having a core/shell structure of Cu₂Se/Cu₂S can be synthesized by first synthesizing Cu₂Se, and then continuously adding the S raw material. Subsequently, the QD 21 having a core/shell structure of ZnSe/ZnS can be synthesized by carrying out metal exchange between Cu and Zn.

In the present embodiment, the S-based material used in the shell 23 is not particularly limited. Examples of the S-based material that can be typically used include thiols.

Examples of the above-mentioned thiols that can be used include octadecanethiol (C₁₈H₃₇SH), hexanedecanethiol (C₁₆H₃₃SH), tetradecanethiol (C₁₄H₂₉SH), dodecanethiol (C₁₂H₂₅SH), decanethiol (C₁₀H₂₁SH), octanethiol (C₈H₁₇SH), benzenethiol (C₆H₅SH), a solution (S-TOP) obtained by dissolving sulfur in a high boiling point solvent that is a long-chain phosphine-based hydrocarbon, such as a trioctylphosphine, a solution (S-ODE) obtained by dissolving sulfur in a high boiling point solvent that is a long-chain hydrocarbon such as octadecene, and a solution (S-DDT/OLAm) obtained by dissolving sulfur in a mixture of oleylamine and dodecanethiol.

The reactivity differs depending on the used S raw material, and as a result, the covering thickness of the shell 23 (for example, ZnS) may be made to differ. The thiol system is proportional to the degradation rate thereof, and the reactivity of S-TOP or S-ODE varies in proportion to the stability thereof. Through this, the covering thickness of the shell 23 and the final fluorescence quantum yield may be controlled by properly using the S raw material.

In the present embodiment, examples of the Zn raw material that can be used in the core-shell structure include a Zn raw material such as the organic zinc compound, the inorganic zinc compound or the like described above.

With regard to the solvent used at the time of covering with the shell 23, as the amount in content of an amine-based solvent is smaller, it is easier to form the cover with the shell 23, thereby making it possible to obtain favorable light-emission characteristics. Further, the light-emission characteristics after covering with the shell 23 differ depending on the ratio of the amine-based solvent, carboxylic acid-based solvent, or phosphine-based solvent.

Furthermore, the QDs 21 synthesized by the manufacturing method of the present embodiment are aggregated by adding a polar solvent as a poor solvent, such as methanol, ethanol, acetone or the like, therefore the QDs 21 and the unreacted raw materials are separated from each other, thereby recovering the QDs 21. The recovered QDs 21 are again dispersed by adding thereto toluene, hexane, or the like once again. By adding a solvent to become the ligands 26 to the re-dispersed solution, the light-emission characteristics and the stability of the light-emission characteristics may be further improved. A change in the light-emission characteristics brought by the addition of the ligands 26 differs significantly depending on the presence or absence of the covering operation with the shell 23. In particular, the fluorescence stability of the QD 21 covered with the shell 23 may be improved by adding the thiol-based ligands 26.

### EXAMPLE

Next, effects of the QD 21 and the light-emitting element 1 according to the present embodiment will be described through examples and comparative examples. Note that the QD 21 and the light-emitting element 1 according to the present embodiment are not limited to the following examples.

First, synthesis examples of the QD 21 according to the present embodiment will be described.

In the following synthesis examples, “Farmin” available from Kao Corporation was used as the oleylamine (OLAm). “Lunac O—V” available from Kao Corporation was used as the oleic acid (OLAc). “Thiokalcol 20” available from Kao Corporation was used as the dodecanethiol (DDT). Furthermore, an anhydrous copper acetate available from Wako Pure Chemical Industries, Ltd. was used as the anhydrous copper acetate. An octadecene available from Idemitsu Kosan Co., Ltd. was used as the octadecene (ODE). A trioctylphosphine available from Hokko Chemical Industry Co., Ltd. was used as the trioctylphosphine (TOP). An anhydrous zinc acetate available from Kishida Chemical Co., Ltd. was used as the anhydrous zinc acetate (Zn(OAc)₂).

### Synthesis Example of QD 21

A 100-mL reaction vessel was charged with 182 mg of anhydrous copper acetate (Cu(OAc)₂) as a Cu raw material (organic copper compound), 4.8 mL of oleylamine (OLAm) as a ligand, and 7.75 mL of octadecene (ODE) as a solvent. The raw materials in the reaction vessel were then heated and dissolved at 163° C. for 10 minutes in an inert gas (N₂) atmosphere while being stirred, whereby a solution was obtained.

Subsequently, 1.14 mL of an Se-DDT/OLAm solution (0.7 M) as an organic chalcogen compound was added to the obtained solution, and the resulting mixture was heated at 163° C. for 30 minutes while being stirred. The reaction solution (Cu₂Se reaction liquid, copper chalcogenide) thereby obtained was cooled to room temperature.

Subsequently, 1844 mg of anhydrous zinc acetate (Zn(OAc)₂) as an organic zinc compound, 10 mL of trioctylphosphine (TOP) as a solvent, and 0.4 mL of oleylamine (OLAm) as a ligand were added to the Cu₂Se reaction liquid, and the resulting mixture was heated at 180° C. for 60 minutes in an inert gas (N₂) atmosphere while being stirred. As a result, a metal exchange reaction occurred between Cu of the copper chalcogenide and Zn. The resulting reaction solution (ZnSe solution) was cooled to room temperature.

Next, toluene as a solvent and ethanol as a poor solvent were added to the reaction solution having been cooled to room temperature to generate precipitate, and the reaction solution was centrifuged to recover the precipitate (cleaning and separation). Subsequently, 24 mL of octadecene (ODE) was added as a solvent (dispersion medium) to the recovered precipitate to disperse the precipitate, whereby a ZnSe-ODE dispersion was obtained. The cleaning and separation refers to a step of separating the particles in the reaction solution by controlling the degree of aggregation due to a difference in the coordination state of the ligands by the ratio of a solvent (nonpolar solvent (no polarity solvent)) such as toluene to a poor solvent (polar solvent) such as ethanol.

Thereafter, 1844 mg of anhydrous zinc acetate (Zn(OAc)₂) as an organic zinc compound, and 10 mL of trioctylphosphine (TOP), 1.0 mL of oleylamine (OLAm) and 6 mL of oleic acid (OLAc) as ligands were added to 24 mL of the ZnSe-ODE dispersion, and the mixture was heated at 280° C. for 20 minutes in an inert gas (N₂) atmosphere while being stirred. The resulting reaction solution (ZnSe dispersion) was cooled to room temperature.

The fluorescence wavelength and the fluorescence full-width at half-maximum of ZnSe in this reaction solution (ZnSe dispersion) were measured using a fluorescence spectrometer. “F-2700” fluorescence spectrometer available from JASCO Corporation was used as the fluorescence spectrometer. The measurement results indicated optical characteristics including a fluorescent peak wavelength of approximately 447 nm and a fluorescence full-width at half-maximum of approximately 14 nm.

In addition, ethanol was added to several mL of the reaction solution (ZnSe dispersion) to generate precipitate, and the reaction solution was centrifuged to recover (isolate) the precipitate. Hexane was added as a solvent (dispersion medium) to the recovered precipitate, and the precipitate was dispersed.

The fluorescence quantum yield of the ZnSe dispersed in the hexane was measured using a quantum efficiency measurement system. “QE-1100” quantum efficiency measurement system available from Otsuka Electronics Co., Ltd. was used as the quantum efficiency measurement system. The measurement results indicated that the fluorescence quantum yield was approximately 46%. The fluorescence lifetime of the ZnSe dispersed in the hexane was measured using a fluorescence lifetime measuring device, and was found to be 18 ns. Note that “C11367” fluorescence lifetime measuring device available from Hamamatsu Photonics K.K. was used to measure the fluorescence lifetime.

The particle size of the ZnSe dispersed in the hexane was measured using a scanning transmission electron microscope (STEM). The X-ray diffraction (XRD) spectrum of the ZnSe dispersed in the hexane was measured using an X-ray diffraction device. “SU9000” available from Hitachi High-Tech Corporation was used as the scanning transmission electron microscope. Furthermore, “D2 PHASER” X-ray diffraction device available from Bruker Corporation was used as the X-ray diffraction device.

As a result, the particle size of the ZnSe was found to be approximately 8.3 nm. This particle size was calculated from the average value of observed samples in the particle observation using the SEM mentioned above. Additionally, it was found that the ZnSe crystal was a cubic crystal, and the peak position thereof was consistent with the crystal peak position of ZnSe.

Next, 20 mL of the reaction solution (ZnSe dispersion) was collected, then toluene as a solvent, and ethanol and methanol as poor solvents were added thereto to generate precipitate, and the mixture was centrifuged to recover the precipitate (cleaning and separation). Subsequently, 17.5 mL of octadecene (ODE) was added as a solvent (dispersion medium) to the recovered precipitate to disperse the precipitate. As a result, obtained was a ZnSe-ODE dispersion in which ZnSe particles (also referred to simply as “ZnSe”) as cores were dispersed in the octadecene (ODE).

Thereafter, 1 mL of oleic acid (OLAc) as ligands and 2 mL of trioctylphosphine (TOP) as a solvent (dispersion medium) were added to 17.5 mL of the ZnSe-ODE dispersion, and the mixture was heated at 320° C. for 10 minutes in an inert gas (N₂) atmosphere while being stirred.

Subsequently, 0.5 mL of a mixed solution (A) describe below was added to the solution thereby obtained, and the resulting mixture was heated at 320° C. for 10 minutes while being stirred, whereby the ZnSe as a core was covered with the ZnSeS as a shell. The mixed solution (A) is a mixed solution of 0.125-mL dodecanethiol (DDT) as an S raw material, 0.5-mL Se-TOP (1.0 M) as an Se raw material, 2.5-mL octadecene (ODE) as a solvent (dispersion medium), 0.375-mL trioctylphosphine (TOP) as ligands, and a 2.5-mL zinc oleate (Zn(OLAc)₂) solution (0.8 M) as an organic zinc compound. In the present synthesis example, the above operation (covering operation with shells) was repeated four times. That is, in the present synthesis example, “adding the mixed solution (A) and heating at 320° C. for 10 minutes while being stirred” was taken as one operation (covering operation with shells), and this operation (covering operation with shells) was repeated four times. As a result, obtained was a reaction solution (ZnSe/ZnSeS dispersion) containing ZnSe/ZnSeS particles (also referred to simply as “ZnSe/ZnSeS”), where the ZnSe as a core was covered with the ZnS as a shell.

Subsequently, toluene as a solvent, and acetone and ethanol as poor solvents were added to the whole quantity of the reaction solution (ZnSe/ZnSeS dispersion) to generate precipitate, and the mixture was centrifuged to recover the precipitate) (cleaning and separation). Subsequently, 17.5 mL of octadecene (ODE) was added as a solvent (dispersion medium) to the recovered precipitate to disperse the precipitate. As a result, obtained was a ZnSe/ZnSeS-ODE dispersion in which ZnSe/ZnSeS particles (also referred to simply as “ZnSe/ZnSeS”) each constituted by the ZnSe as a core being covered with the ZnSeS as a shell are dispersed in octadecene (ODE).

Subsequently, 0.5 mL of a mixed solution (B) describe below was added to the ZnSe/ZnSeS-ODE dispersion, and the resulting mixture was heated at 320° C. for 10 minutes while being stirred, whereby the ZnSe/ZnSeS particle was covered with the ZnS as a shell. The mixed solution (B) is a mixed solution of 0.5-mL dodecanethiol (DDT) as an S raw material, 5-mL octadecene as a solvent (dispersion medium), 1.5-mL trioctylphosphine (TOP) as ligands, and a 5-mL zinc oleate (Zn(OLAc)₂) solution (0.8 M) as an organic zinc compound. In the present synthesis example, this operation (covering operation with shells) was repeated 10 times. That is, in the present synthesis example, “adding the mixed solution (B) and heating at 320° C. for 10 minutes while being stirred” was taken as one operation (covering operation with shells), and this operation (covering operation with shells) was repeated four times. As a result, obtained was a reaction solution (ZnSe/ZnSeS/ZnS (1) dispersion) containing ZnSe/ZnSeS/ZnS particles (also referred to as “ZnSe/ZnSeS/ZnS (1)”) constituted by the ZnSe as a core being covered with the ZnSeS and ZnS as shells in that order from the core side.

Subsequently, toluene as a solvent, and acetone and ethanol as poor solvents were added to the whole quantity of the reaction solution (ZnSe/ZnSeS/ZnS (1) dispersion) to generate precipitate, and the mixture was centrifuged to recover the precipitate (ZnSe/ZnSeS/ZnS (1)) (cleaning and separation). Then, 17.5 mL of octadecene (ODE) was added as a solvent (dispersion medium) to the recovered precipitate to disperse the precipitate, whereby a ZnSe/ZnSeS/ZnS (1)-ODE dispersion was obtained in which the ZnSe/ZnSeS/ZnS (1) was dispersed in the octadecene (ODE).

Subsequently, 0.5 mL of a mixed solution (C) having the same composition as the mixed solution (B) was added to the ZnSe/ZnSeS/ZnS (1)-ODE dispersion, and the resulting mixture was heated at 320° C. for 10 minutes while being stirred, whereby the ZnSe/ZnSeS/ZnS (1) was further covered with the ZnS as a shell. The mixed solution (C) is a mixed solution of 0.5-mL dodecanethiol (DDT) as an S raw material, 5-mL octadecene as a solvent (dispersion medium), 1.5-mL trioctylphosphine (TOP) as ligands, and 5-mL zinc oleate (Zn(OLAc)₂) solution (0.8 M) as an organic zinc compound. In the present synthesis example, the above operation (covering operation with shells) was repeated six times. That is, in the present synthesis example, “adding the mixed solution (C) and heating at 320° C. for 10 minutes while being stirred” was taken as one operation (covering operation with shells), and this operation (covering operation with shells) was repeated six times. As a result, obtained was a reaction solution (ZnSe/ZnSeS/ZnS (2) dispersion) containing ZnSe/ZnSeS/ZnS particles (also referred to as “ZnSe/ZnSeS/ZnS (2)”) constituted by the ZnSe/ZnSeS/ZnS (1) being further covered with the ZnS as a shell.

Subsequently, toluene as a solvent, and acetone and ethanol as poor solvents were added to the whole quantity of the reaction solution (ZnSe/ZnSeS/ZnS (2) dispersion) to generate precipitate, and the mixture was centrifuged to recover the precipitate (ZnSe/ZnSeS/ZnS (2)) (cleaning and separation). Then, 17.5 mL of octadecene (ODE) was added as a solvent (dispersion medium) to the recovered precipitate to disperse the precipitate, whereby a ZnSe/ZnSeS/ZnS (2)-ODE dispersion was obtained in which the ZnSe/ZnSeS/ZnS (2) was dispersed in the octadecene (ODE).

Subsequently, 0.5 mL of a mixed solution (D) having the same composition as the mixed solutions (B) and (C) was added to the ZnSe/ZnSeS/ZnS (2)-ODE dispersion, and the resulting mixture was heated at 320° C. for 10 minutes while being stirred, whereby the ZnSe/ZnSeS/ZnS (2) was further covered with the ZnS as a shell. The mixed solution (D) is a mixed solution of 0.5-mL dodecanethiol (DDT) as an S raw material, 5-mL octadecene as a solvent (dispersion medium), 1.5-mL trioctylphosphine (TOP) as ligands, and a 5-mL zinc oleate (Zn(OLAc)₂) solution (0.8 M) as an organic zinc compound. In the present synthesis example, the above operation (covering operation with shells) was repeated six times. As a result, obtained was a reaction solution (ZnSe/ZnSeS/ZnS (3) dispersion) containing ZnSe/ZnSeS/ZnS particles (also referred to as “ZnSe/ZnSeS/ZnS (3)”) constituted by the ZnSe/ZnSeS/ZnS (2) being further covered with the ZnS as a shell.

Subsequently, toluene as a solvent, and acetone and ethanol as poor solvents were added to the whole quantity of the reaction solution (ZnSe/ZnSeS/ZnS (3) dispersion) to generate precipitate, and the mixture was centrifuged to recover the precipitate (ZnSe/ZnSeS/ZnS (3)) (cleaning and separation). Then, 17.5 mL of octadecene (ODE) was added as a solvent (dispersion medium) to the recovered precipitate to disperse the precipitate, whereby a ZnSe/ZnSeS/ZnS (3)-ODE dispersion was obtained in which the ZnSe/ZnSeS/ZnS (3) was dispersed in the octadecene (ODE).

Subsequently, 0.5 mL of a mixed solution (E) having the same composition as the mixed solutions (B) to (D) was added to the ZnSe/ZnSeS/ZnS (3)-ODE dispersion, and the resulting mixture was heated at 320° C. for 10 minutes while being stirred, whereby the ZnSe/ZnSeS/ZnS (3) was further covered with the ZnS as a shell. The mixed solution (E) is a mixed solution of 0.5-mL dodecanethiol (DDT) as an S raw material, 5-mL octadecene as a solvent (dispersion medium), 1.5-mL trioctylphosphine (TOP) as ligands, and a 5-mL zinc oleate (Zn(OLAc)₂) solution (0.8 M) as an organic zinc compound. In the present synthesis example, the above operation (covering operation with shells) was repeated six times. With this, as the QDs 21 according to the present embodiment, obtained was a reaction solution (ZnSe/ZnSeS/ZnS (4) dispersion) containing ZnSe/ZnSeS/ZnS particles (also referred to as “ZnSe/ZnSeS/ZnS (4)”) constituted by the ZnSe/ZnSeS/ZnS (3) being further covered with the ZnS as a shell.

The fluorescence wavelength and the fluorescence full-width at half-maximum of the ZnSe/ZnSeS/ZnS (4) in this reaction solution (ZnSe/ZnSeS/ZnS (4) dispersion) were measured using a fluorescence spectrometer. The “F-2700” fluorescence spectrometer available from JASCO Corporation was used as the fluorescence spectrometer. The measurement results indicated optical characteristics including a fluorescent peak wavelength of approximately 443 nm and a fluorescence full-width at half-maximum of approximately 15 nm.

Subsequently, ethanol as a poor solvent was added to the above reaction solution (ZnSe/ZnSeS/ZnS (4) dispersion) to generate precipitate, and the mixture was centrifuged to recover (isolate) the precipitate (ZnSe/ZnSeS/ZnS (4)). Thereafter, hexane was added as a solvent (dispersion medium) to the precipitate (ZnSe/ZnSeS/ZnS (4)) to disperse the precipitate. As a result, a ZnSe/ZnSeS/ZnS (4)-hexane dispersion was obtained in which the ZnSe/ZnSeS/ZnS (4) as the QD 21 was dispersed in the hexane as a solvent (dispersion medium).

The fluorescence quantum yield of the ZnSe/ZnSeS/ZnS (4) dispersed in the hexane was measured using the quantum efficiency measurement system described above. The measurement result indicated that the fluorescence quantum yield was approximately 64%. The fluorescence lifetime of the ZnSe/ZnSeS/ZnS (4) dispersed in the hexane was measured using the fluorescence lifetime measuring device described above, and was found to be 15 ns.

In the present synthesis example, the particle sizes (outermost particle sizes) of the obtained particles (ZnSe/ZnSeS particles and ZnSe/ZnSeS/ZnS particles) were measured with the above-described scanning transmission electron microscope every time covering with shells is carried out.

As a result, in the above-described ZnSe/ZnSeS-ODE dispersion, the particle size (outermost particle size) of the ZnSe/ZnSeS (ZnSe/ZnSeS particles) dispersed in the octadecene (ODE) was about 10.3 nm, and it was confirmed that the shell thickness increased by 1 nm due to the ZnSe being covered with the ZnSeS. The particle size (outermost particle size) of the ZnSe/ZnSeS/ZnS (4) dispersed in the hexane described above was about 12.3 nm, and it was confirmed that the shell thickness further increased by 1 nm due to the ZnSe/ZnSeS being covered with the ZnS.

That is, it was confirmed that the particle size (diameter) of the core of the QD 21 (ZnSe/ZnSeS/ZnS (4)) obtained in this synthesis example was about 8.3 nm as described above, the film thickness (total thickness) of the shell of the QD 21 was 2 nm, and of the total thickness, the layer thickness of the ZnSeS layer was 1 nm and the layer thickness of the ZnS layer was 1 nm.

In the present synthesis example, the X-ray diffraction spectra of the obtained particles (ZnSe/ZnSeS particles and ZnSe/ZnSeS/ZnS particles) were measured using the above-described X-ray diffraction device every time covering with shells was carried out.

As a result, it was found that the crystal of the ZnSe/ZnSeS/ZnS (4) was a cubic crystal, and the maximum peak intensity thereof was shifted toward a higher angle side relative to the crystal peak position of ZnSe.

In addition, from the X-ray diffraction spectra discussed above, it was confirmed that when a raw material containing ZnS having a smaller lattice constant than ZnSe used for the core was used as a raw material used at the time of covering with shells, the peak of the maximum intensity of the X-ray diffraction spectrum of the QD 21 was likely to shift toward the higher angle side as the core was covered with the shell. From the peak shift toward the higher angle side, it is understood that the lattice constant changes by covering the core with the shell. That is, by covering the core with the shell, the lattice constant of the QD 21 becomes smaller than that before the covering.

As described above, according to the present example, by covering the core with the shell, the peak of the maximum intensity of the X-ray diffraction spectrum is shifted toward the higher angle side, and thus high external quantum efficiency (EQE) may be achieved.

According to the present embodiment, as described above, an environment-friendly QD may be provided by using a QD containing no Cd, that is, using the QD 21 made of a non-Cd-based material.

### Example 1

The light-emitting element 1 having the following layered structure was manufactured as a sample (1) using the QD 21 synthesized by the method described in the section “Synthesis Example of QD 21”.

ITO (30 nm)/PEDOT:PSS (40 nm)/PVK (25 nm)/QD Layer (25 nm)/ZnO (50 nm)/Al (100 nm)

Specifically, first, the anode electrode 12 having a thickness of 30 nm was formed by sputtering ITO on the substrate 11, which was a glass substrate. Next, a solution containing PEDOT:PSS was applied by spin coating onto the anode electrode 12. Thereafter, a solvent in the above-mentioned solution applied onto the anode electrode 12 was volatilized by baking to form the hole injection layer 13 (PEDOT:PSS layer) having a layer thickness of 40 nm. Subsequently, a solution containing PVK was applied onto the hole injection layer 13 by spin coating. Thereafter, a solvent in the above-mentioned solution applied onto the hole injection layer 13 was volatilized by baking to form the hole transport layer 14 (PVK layer) having a layer thickness of 25 nm. Subsequently, the ZnSe/ZnSeS/ZnS (4)-hexane dispersion (liquid composition, QD solution) synthesized by the method described in the section “Synthesis Example of QD 21” was applied by spin coating onto the hole transport layer 14. Thereafter, a solvent (hexane) in the above-mentioned ZnSe/ZnSeS/ZnS (4)-hexane dispersion applied onto the hole transport layer 14 was volatilized by baking to form the QD layer 15 (ZnSe/ZnSeS/ZnS (4) layer) having a layer thickness of 25 nm. Subsequently, a solution containing ZnO nanoparticles was applied onto the QD layer 15 by spin coating. A solvent in the above-mentioned solution applied onto the QD layer 15 was volatilized by baking to form the electron transport layer 16 (ZnO nanoparticle layer) having a layer thickness of 50 nm. Next, the cathode electrode 17 having a thickness of 100 nm was formed by vacuum vapor deposition of Al onto the electron transport layer 16. Subsequently, the substrate 11 and the layered body formed on the substrate 11 were sealed with a sealing member in an N₂ atmosphere.

Next, a current (more precisely, a current density) in a range from 0.03 mA/cm² to 75 mA/cm² was applied to the above-mentioned sample (1). Then, by applying the current, the light emission spectrum of LB emitted from the sample (1) was measured using an LED measuring device (spectrometer). Note that as the LED measuring device, an LED measuring device available from Spectra Co-op (two-dimensional CCD small high sensitivity spectrometer: Solid Lambda CCD available from Carl Zeiss AG) was used.

Thereafter, based on the measured light emission spectrum, a variation in the light emission peak wavelength by the operation voltage of the sample (1) was calculated.

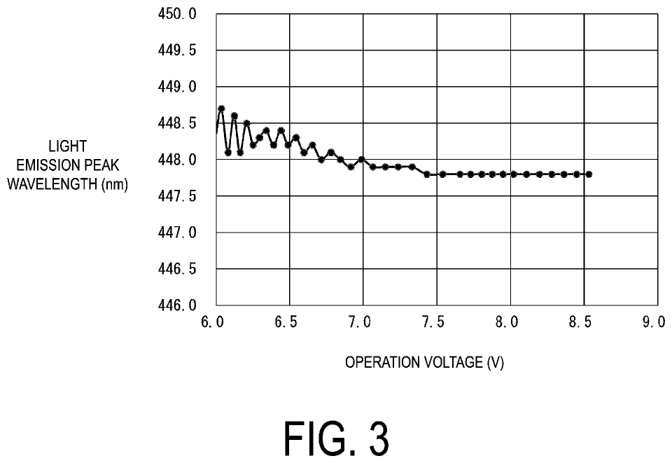

FIG. 3 is a graph showing a relationship between the operation voltage and a variation in the light emission peak wavelength of the light-emitting element 1 (sample (1)) manufactured in the present example.

As shown in FIG. 3, the variation in the light emission peak wavelength (fluorescent peak wavelength) at the operation voltage of Vmin to Vmax of the sample (1) was equal to or less than 1 nm. From this, it is understood that the sample (1) is an element having a small variation in the light emission peak wavelength (fluorescent peak wavelength) by the operation voltage and having good color reproducibility. As can be understood from FIG. 3, Vmax of the sample (1) was set to 8 V. The operation voltage (Vmin) at which the luminance was 5 cd/m² or more was 6.0 V.

As described above, the QD 21 (ZnSe/ZnSeS/ZnS (4)) synthesized by the method described in the section “Synthesis Example of QD 21” had a fluorescent peak wavelength of about 443 nm and a fluorescence quantum yield of about 64%.

The external quantum efficiency (%) is expressed by (carrier balancing)×(generation efficiency of luminescent excitons)×(photoluminescence quantum yield (fluorescence quantum yield))×(light extraction efficiency), and is proportional to the photoluminescence quantum yield (fluorescence quantum yield).

According to the present example, the following can be understood from the results described above: it is possible to obtain the Cd-free QD 21 configured to emit blue light and capable of achieving the light-emitting element 1 having a small variation in the light emission peak wavelength when the operation voltage is applied, having excellent color reproducibility, and having high external quantum efficiency.

As described above, the fluorescence lifetime of the QD 21 (ZnSe/ZnSeS/ZnS (4)) synthesized by the method described in the section “Synthesis Example of QD 21” was 15 ns, and the fluorescence full-width at half-maximum thereof was approximately 15 nm. Therefore, according to the present example, it can be understood that it is possible to obtain the Cd-free QD 21 configured to emit blue light and capable of achieving the light-emitting element 1 having a small variation in the light emission peak wavelength when the operation voltage is applied, having excellent color reproducibility, having a narrow fluorescence full-width at half-maximum, having a short fluorescence lifetime, capable of emitting the blue light with high luminance, and having high external quantum efficiency. According to the present example, it is understood that it is possible to obtain the light-emitting element 1 including the QD 21, having small variation in the light emission peak wavelength when the operation voltage is applied, having excellent color reproducibility, having a narrow fluorescence full-width at half-maximum, having a short fluorescence lifetime, capable of emitting blue light with high luminance, and having high external quantum efficiency.

### Example 2

The same reactions and operations as those in Example 1 were performed except that the layer thickness of the QD layer 15 (ZnSe/ZnSeS/ZnS (4) layer) was changed from 25 nm to 35 nm in Example 1. With this, the light-emitting element 1 having the following layered structure was manufactured as a sample (2) using the QD 21 synthesized by the method described in the section “Synthesis Example of QD 21”.

ITO (30 nm)/PEDOT:PSS (40 nm)/PVK (25 nm)/QD Layer (35 nm)/ZnO (50 nm)/Al (100 nm)

Next, using the sample (2), a variation in the light emission peak wavelength by the operation voltage of the sample (2) was calculated by the same method as in Example 1.

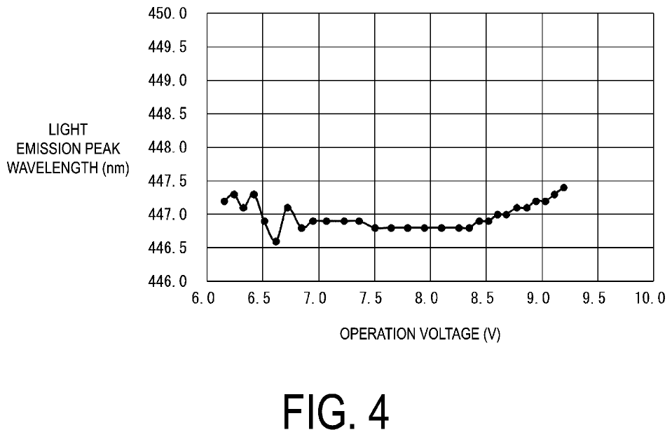

FIG. 4 is a graph showing a relationship between the operation voltage and a variation in the light emission peak wavelength of the light-emitting element 1 (sample (2)) manufactured in the present example.

As shown in FIG. 4, the variation in the light emission peak wavelength (fluorescent peak wavelength) at the operation voltage of Vmin to Vmax of the sample (2) was also equal to or less than 1 nm. From this, it is understood that the sample (2) is also an element having a small variation in the light emission peak wavelength (fluorescent peak wavelength) by the operation voltage and having good color reproducibility. As can be understood from FIG. 4, Vmax of the sample (2) was set to 8 V. The operation voltage (Vmin) at which the luminance was 5 cd/m² or more was 6.2 V.

As described above, in the present example as well, the QD 21 (ZnSe/ZnSeS/ZnS (4)) synthesized by the method described in the section “Synthesis Example of QD 21” was used for the QD layer 15 as in Example 1.

Accordingly, in the present example as well, it can be understood that it is possible to obtain the Cd-free QD 21 configured to emit blue light and capable of achieving the light-emitting element 1 having a small variation in the light emission peak wavelength when the operation voltage is applied, having excellent color reproducibility, having a narrow fluorescence full-width at half-maximum, having a short fluorescence lifetime, capable of emitting the blue light with high luminance, and having high external quantum efficiency. In the present example as well, it is understood that it is possible to obtain the light-emitting element 1 including the QD 21, having a small variation in the light emission peak wavelength when the operation voltage is applied, having excellent color reproducibility, having a narrow fluorescence full-width at half-maximum, having a short fluorescence lifetime, capable of emitting blue light with high luminance, and having high external quantum efficiency.

### Example 3

The same reactions and operations as those in Example 1 were performed except that the layer thickness of the QD layer 15 (ZnSe/ZnSeS/ZnS (4) layer) was changed from 25 nm to 45 nm in Example 1. With this, the light-emitting element 1 having the following layered structure was manufactured as a sample (3) using the QD 21 synthesized by the method described in the section “Synthesis Example of QD 21”.

ITO (30 nm)/PEDOT:PSS (40 nm)/PVK (25 nm)/QD layer (45 nm)/ZnO (50 nm)/Al (100 nm)

Next, using the sample (3), a variation in the light emission peak wavelength by the operation voltage of the sample (3) was calculated by the same method as in Example 1.

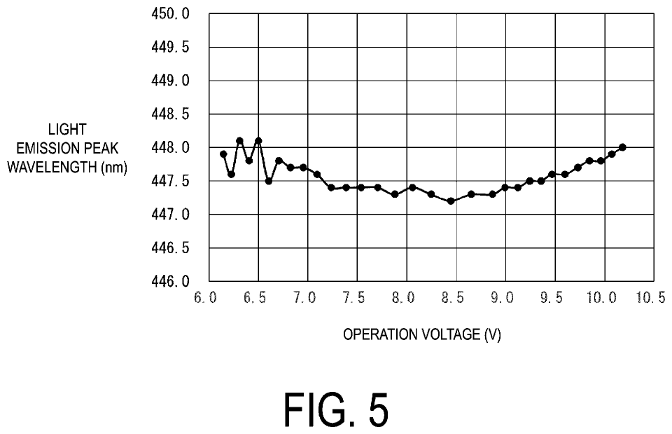

FIG. 5 is a graph showing a relationship between the operation voltage and a variation in the light emission peak wavelength of the light-emitting element 1 (sample (3)) manufactured in the present example.

As shown in FIG. 5, the variation in the light emission peak wavelength (fluorescent peak wavelength) at the operation voltage of Vmin to Vmax of the sample (3) was also equal to or less than 1 nm. From this, it is understood that the sample (2) is also an element having a small variation in the light emission peak wavelength (fluorescent peak wavelength) by the operation voltage and having good color reproducibility. As can be understood from FIG. 5, Vmax of the sample (3) was set to 8 V. The operation voltage (Vmin) at which the luminance was 5 cd/m² or more was 6.1 V.

As described above, in the present example as well, the QD 21 (ZnSe/ZnSeS/ZnS (4)) synthesized by the method described in the section “Synthesis Example of QD 21” was used for the QD layer 15 as in Example 1.

Accordingly, in the present example as well, it can be understood that it is possible to obtain the Cd-free QD 21 configured to emit blue light and capable of achieving the light-emitting element 1 having a small variation in the light emission peak wavelength when the operation voltage is applied, having excellent color reproducibility, having a narrow fluorescence full-width at half-maximum, having a short fluorescence lifetime, capable of emitting the blue light with high luminance, and having high external quantum efficiency. In the present example as well, it is understood that it is possible to obtain the light-emitting element 1 including the QD 21, having a small variation in the light emission peak wavelength when the operation voltage is applied, having excellent color reproducibility, having a narrow fluorescence full-width at half-maximum, having a short fluorescence lifetime, capable of emitting blue light with high luminance, and having high external quantum efficiency.

### Comparative Example

A 300 mL reaction vessel was charged with 543 mg of anhydrous copper acetate (Cu(OAc)₂) as a Cu raw material (organic copper compound), 28.5 mL of oleylamine (OLAm) as a ligand, and 46.5 mL of octadecene (ODE) as a solvent. The raw materials in the reaction vessel were then heated and dissolved at 150° C. for 20 minutes in an inert gas (N₂) atmosphere while being stirred, and a solution was thereby obtained.

Next, 8.4 mL of an Se-DDT/OLAm solution (0.285 M) was added as an organic chalcogen compound to the solution, and the resulting mixture was heated at 150° C. for 10 minutes while being stirred. The reaction solution (Cu₂Se reaction liquid, copper chalcogenide) thereby obtained was cooled to room temperature.

Subsequently, 4.092 g of anhydrous zinc acetate (Zn(OAc)₂) as an organic zinc compound, 60 mL of trioctylphosphine (TOP) as a solvent, and 2.4 mL of oleylamine (OLAm) as a ligand were added to the Cu₂Se reaction liquid, and the resulting mixture was heated at 180° C. for 30 minutes in an inert gas (N₂) atmosphere while being stirred. As a result, a metal exchange reaction occurred between Cu of the copper chalcogenide and Zn. The resulting reaction solution (ZnSe solution) was cooled to room temperature.

Next, ethanol was added to the reaction solution cooled to room temperature to generate precipitate, and the reaction solution was centrifuged to recover the precipitate. Then, 72 mL of octadecene (ODE) was added as a solvent (dispersion medium) to the recovered precipitate to disperse the precipitate, whereby a ZnSe-ODE dispersion was obtained.

Thereafter, 4.092 g of anhydrous zinc acetate (Zn(OAc)₂) as an organic zinc compound, 30 mL of trioctylphosphine (TOP) as a solvent (dispersion medium), and 3 mL of oleylamine (OLAm) and 36 mL of oleic acid (OLAc) as ligands were added to 72 mL of the ZnSe-ODE dispersion, and the mixture was heated at 280° C. for 30 minutes in an inert gas (N₂) atmosphere while being stirred. The resulting reaction solution (ZnSe dispersion) was cooled to room temperature.

The fluorescence wavelength and the fluorescence full-width at half-maximum of the ZnSe in this reaction solution (ZnSe dispersion) were measured using the fluorescence spectrometer described above. The measurement results indicated optical characteristics including a fluorescent peak wavelength of approximately 430.5 nm and a fluorescence full-width at half-maximum of approximately 15 nm.

The fluorescence quantum yield of the ZnSe in the reaction solution (ZnSe dispersion) was measured using the quantum efficiency measurement system mentioned above. The measurement results showed that the fluorescence quantum yield was approximately 30%. The fluorescence lifetime of the ZnSe in the reaction solution (ZnSe dispersion) was measured by the fluorescence lifetime measuring device discussed above, and was found to be 48 ns.

Further, the particle size of the ZnSe in the reaction solution (ZnSe dispersion) was measured using a scanning transmission electron microscope. Furthermore, the X-ray diffraction spectrum of the ZnSe in the reaction solution (ZnSe dispersion) was measured using an X-ray diffraction device.

As a result, the particle size of the ZnSe was found to be approximately 5 nm. This particle size was calculated from the average value of the observed samples in the particle observation using the scanning transmission electron microscope described above. Additionally, it was found that the ZnSe crystal was a cubic crystal, and the peak position thereof was consistent with the crystal peak position of ZnSe.

Subsequently, 47 mL of the reaction solution (ZnSe dispersion) was collected, ethanol as a poor solvent was added thereto to generate precipitate, and the mixture was centrifuged to recover the precipitate. Then, 35 mL of octadecene (ODE) was added as a solvent (dispersion medium) to the recovered precipitate to disperse the precipitate. As a result, obtained was a ZnSe-ODE dispersion in which ZnSe particles (also referred to simply as “ZnSe”) as cores were dispersed in the octadecene (ODE).

Subsequently, 35 mL of the ZnSe-ODE dispersion was heated at 310° C. for 20 minutes in an inert gas (N₂) atmosphere while being stirred.

Subsequently, a mixed solution of 2.2 mL of an S-TOP solution (2.2 M) as an S raw material and 11 mL of a zinc oleate (Zn(OLAc)₂) solution (0.8 M) as an organic zinc compound was prepared, and 1.1 mL of the mixed solution was added to the ZnSe-ODE dispersion; then, the mixture was heated at 310° C. for 20 minutes while being stirred, whereby the ZnSe (core size of 5.3 nm) as a core was covered with the ZnS as a shell. In the present synthesis example, this operation (covering operation with shells) was repeated 12 times. With this, as QDs for comparison, obtained was a reaction solution (ZnSe/ZnS dispersion) containing ZnSe/ZnS particles (also referred to simply as “ZnSe/ZnS”) each constituted by the ZnSe as a core being covered with the ZnS as a shell.

Subsequently, ethanol was added as a poor solvent to the reaction solution (ZnSe/ZnS dispersion) to generate precipitate, and the reaction solution was centrifuged to recover the precipitate (ZnSe/ZnS particles). Next, hexane was added as a solvent (dispersion medium) to the precipitate, and the precipitate was dispersed. Through this, obtained was a ZnSe/ZnS-hexane dispersion with the ZnSe/ZnS as QDs for comparison being dispersed in the hexane as the solvent (dispersion medium).

The fluorescence wavelength and the fluorescence full-width at half-maximum of the ZnSe/ZnS dispersed in the hexane were measured using the fluorescence spectrometer described above. The measurement results indicated optical characteristics including a fluorescent peak wavelength of approximately 423 nm and a fluorescence full-width at half-maximum of approximately 15 nm.

Further, the fluorescence quantum yield of the ZnSe/ZnS dispersed in the hexane was measured using the quantum efficiency measurement system described above. The measurement results showed that the fluorescence quantum yield was approximately 60%. Furthermore, the fluorescence lifetime of the ZnSe/ZnS dispersed in the hexane was measured using the fluorescence lifetime measuring device described above, and was found to be 44 ns.

The particle size (outermost particle size) of the ZnSe/ZnS dispersed in the hexane was measured using the scanning transmission electron microscope described above. Furthermore, the X-ray diffraction spectrum of the ZnSe/ZnS dispersed in the hexane was measured using the X-ray diffraction device described above.

As a result, the particle size (outermost particle size) of the ZnSe/ZnS was about 8.5 nm, and it was confirmed that the shell thickness increased by 1.6 nm due to the ZnSe being covered with the ZnS. Additionally, it was found that the ZnSe/ZnS crystal was a cubic crystal, and the maximum peak intensity thereof was shifted toward a higher angle side by 1.1° relative to the crystal peak position of ZnSe.

Next, the same reactions and operations as those in Example 1 were carried out except that the layer thickness of the hole injection layer 13 (PVK layer) was changed from 25 nm to 35 nm, the ZnSe/ZnS-hexane dispersion was used instead of the ZnSe/ZnSeS/ZnS (4)-hexane dispersion, and the QD layer 15 was formed with ZnSe/ZnS having a layer thickness of 15 nm in Example 1. Thus, a light-emitting element (electroluminescent element) for comparison having the following layered structure was manufactured as a sample (4) using the QDs for comparison.

ITO (30 nm)/PEDOT:PSS (40 nm)/PVK (35 nm)/QD layer (15 nm)/ZnO (50 nm)/Al (100 nm)

Next, using the sample (4), a variation in the light emission peak wavelength by the operation voltage of the sample (4) was calculated by the same method as in Example 1.

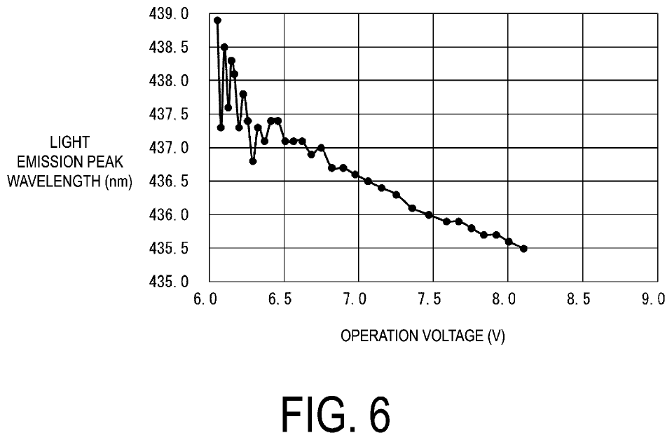

FIG. 6 is a graph showing a relationship between the operation voltage and the variation in the light emission peak wavelength of the light-emitting element (sample (4)) for comparison manufactured in the present comparative example.

As shown in FIG. 6, the variation in the light emission peak wavelength (fluorescent peak wavelength) at the operation voltage of Vmin to Vmax of the sample (4) was 3.5 nm. From this, it is understood that the sample (4) has a large variation in the light emission peak wavelength (fluorescent peak wavelength) by the operation voltage and has unfavorable color reproducibility compared to the light-emitting element 1 in Examples 1 to 3. As can be understood from FIG. 6, Vmax of the sample (4) was set to 8 V. The operation voltage (Vmin) at which the luminance was 5 cd/m² or more was 6.1 V.

### First Modified Example

In the description given above, the case in which the shell 23 in the QD 21 has a dual-layer structure of the innermost layer 23a and the outermost layer 23b is exemplified and explained.

However, as described above, the shell 23 may contain Zn, Se, and S in the boundary portion 24 adjacent to the core 22, and contain Zn and S in the outermost portion 25. Because of this, the shell 23 may have a layered structure in which three or more layers are layered.

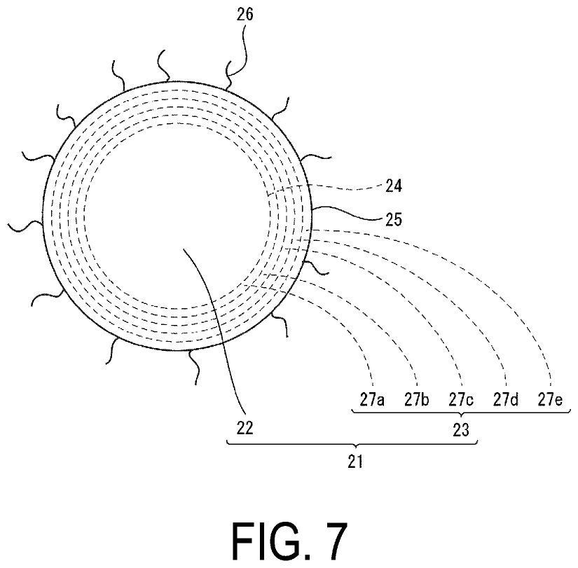

FIG. 7 is a schematic view illustrating another example of the QD 21 according to the present embodiment.

In FIG. 7, a case in which the shell 23 is constituted by layering a first layer 27a, a second layer 27b, a third layer 27c, a fourth layer 27d, and a fifth layer 27e in that order from the boundary portion 24 side toward the outermost portion 25 is illustrated as an example. In the example illustrated in FIG. 7, the first layer 27a is the innermost layer of the shell 23, and the fifth layer 27e is the outermost layer of the shell 23.

In FIG. 7, the boundary between the core 22 and the shell 23 is indicated by a dotted line, which indicates that it does not matter whether the boundary between the core 22 and the shell 23 is confirmed or not confirmed by analysis.

Likewise, in FIG. 7, the boundaries between the layers of the shell 23 are indicated by dotted lines, which indicates that it does not matter whether the boundary of each layer is confirmed or not confirmed by analysis.

As described above, when the shell 23 has a layered structure, the film thickness of the shell 23 is represented by the total thickness of a plurality of the layers constituting the shell 23. The number of layers of the shell 23 may be optionally set in such a manner that the total thickness of the shell 23 falls within a range from 0.5 nm to 3 nm. However, when the number of layers of the shell 23 exceeds five, there arises a fear that the QD 21 may be deteriorated due to the repetition of the covering step with the shell 23. In addition, as the number of times of covering with the shell 23 increases, the manufacturing process of the QD 21 becomes more complicated, thereby leading to an increase in manufacturing costs. Therefore, it is desirable for the number of layers of the shell 23 to be five or less.

Even when the shell 23 includes three or more layers as described above, it is desirable for the layer thickness of each layer of the shell 23 to be 20% or more of the total thickness of the shell 23.

As discussed above, in any layer of the shell 23, when the layer thickness thereof is less than 20% of the film thickness of the shell 23, there is a possibility that the function as the shell cannot be sufficiently exhibited. Therefore, the layer thickness of any layer of the shell 23 is desirably 20% or more of the film thickness of the shell 23. From this point of view as well, it is desirable for the number of layers of the shell 23 to be five or less.

Even when the shell 23 includes three or more layers as described above, it is desirable for the composition of the shell 23 to change in such a manner that the composition ratio of Se in relation to Zn stepwisely decreases and the percentage content of S in relation to Zn stepwisely increases from the boundary portion 24 toward the outermost portion 25.

That is, when the shell 23 includes three or more layers as discussed above, it is desirable for the composition of each layer of the shell 23 to change stepwisely in such a manner that the composition ratio of Se in relation to Zn stepwisely decreases and the percentage content of S in relation to Zn stepwisely increases from the innermost layer toward the outermost layer of the shell 23.

For example, when the composition of the innermost layer of the shell 23 is ZnSe₁₋ₓSₓ and the composition of the outermost layer thereof is ZnS, it is preferable that x of each layer increase in a range of 0<x<1 (favorably 0.2≤x<1), and the band gap of the shell 23 increase from the innermost layer to the outermost layer.

With this, the occurrence of defects due to lattice mismatch of the shell 23 may be suppressed, and the band gap of the shell 23 may be increased from the innermost layer toward the outermost layer. This makes it possible to provide the QD 21 having a high photoluminescence quantum yield.

FIG. 2 and FIG. 7 each illustrate an example of a case in which the shell 23 includes the plurality of layers. However, the present embodiment is not limited to this example.

Even in the case where the shell 23 has a layered structure of three or more layers as illustrated in FIG. 7, the shell 23 may have a structure in which the boundary of each layer is not clearly distinguished by the above-mentioned x gradually changing at the boundary of each layer.

The above-mentioned x gradually changes not only at the boundary of each layer but also from the boundary portion 24 (innermost shell) toward the outermost portion 25 (outermost shell) in the shell 23, whereby the shell 23 may have a structure in which the layers themselves of the shell 23 are not clearly distinguished.

In this case as well, when the composition ratio of Zn:Se:S in the shell 23 is set to 1:1-x:x, it is desirable for x to satisfy a relation of 0.2≤x≤0.8 in the boundary portion 24 and satisfy a relation of x=1 in the outermost portion 25 as described above.

### Second Modified Example

In the description given above, the BE type light-emitting element 1 has been explained. However, the light-emitting element 1 according to the present embodiment is not limited thereto. As described above, the light-emitting element 1 may be a top-emitting (TE) type light-emitting element. An example of a TE type light-emitting element will be described in a third embodiment described below.

In a case where the light-emitting element 1 is of the TE type, the LB is emitted from the QD layer 15 in the upward direction in FIG. 1. Thus, a light-reflective electrode is used for the anode electrode 12, and a light-transmissive electrode is used for the cathode electrode 17. A substrate poorly light-transmissive (e.g., a plastic substrate) may be used as the substrate 11.

In the TE type light-emitting element 1, there are fewer members, such as TFTs, that obstruct the path of the LB on the LB light-emitting face side (emission direction) in comparison with in the BE type light-emitting element 1. As a result, since the aperture ratio is large, the EQE can be further improved.

### Second Embodiment

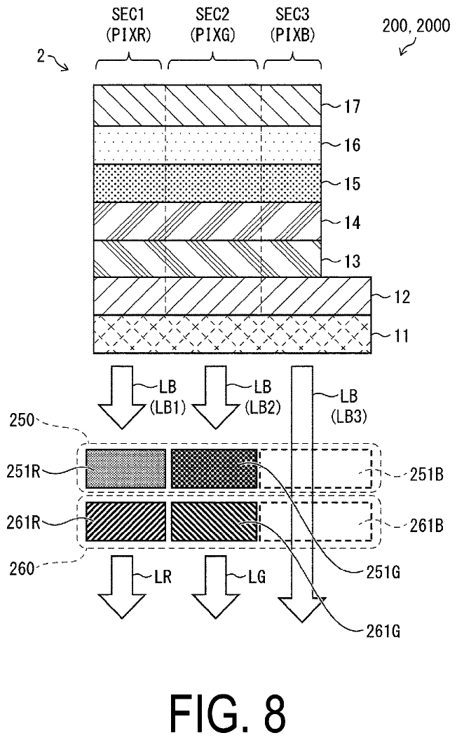

FIG. 8 is a cross-sectional view schematically illustrating an overall configuration of main portions of a display device 2000 according to the present embodiment. The display device 2000 includes a light-emitting device 200. The light-emitting device 200 includes a light-emitting element 2, a wavelength conversion sheet 250 (wavelength conversion member), and a color filter (CF) sheet 260 (CF member). The light-emitting device 200 may be used as, for example, a backlight for the display device 2000. The light-emitting device 200 configures one picture element including an R pixel (PIXR), a G pixel (PIXG), and a B pixel (PIXB) in the display device 2000.

The display device 2000 includes the R pixel (PIXR), the G pixel (PIXG), and the B pixel (PIXB). Note that the R pixel may be referred to as an R subpixel. This similarly applies to the G pixel and the B pixel.

The light-emitting element 2 is a BE type electroluminescent element similar to the light-emitting element 1. In the example illustrated in FIG. 8, a display portion (not illustrated) (for example, a display panel) of the display device 2000 is provided below the light-emitting element 2.

In the light-emitting element 2, the QD layer 15 (and each corresponding layer) is partitioned into three subregions (SEC1 to SEC3) in a horizontal direction. More specifically, in the light-emitting element 2, a plurality of TFTs (not illustrated) are provided in each of the SEC1 to SEC3, therefore individual voltages can be applied to the QD layer 15. Accordingly, the light emission state of the QD layer 15 can be individually controlled in each of the SEC1 to SEC3.

The LBs that are emitted from the SEC1 to SEC3 are also referred to below as LB1 to LB3, respectively. In the example of FIG. 8, the SEC1 is set as a subregion corresponding to the PIXR, the SEC2 is set as a subregion corresponding to the PIXG, and the SEC3 is set as a subregion corresponding to the PIXB.

The wavelength conversion sheet 250 is provided below the light-emitting element 2 at a position corresponding to the SEC1 to SEC3. The wavelength conversion sheet 250 converts a wavelength of a portion of the LB (LB1 and LB2) emitted from the QD layer 15. The wavelength conversion sheet 250 includes a red wavelength conversion layer 251R (red wavelength conversion member) and a green wavelength conversion layer 251G (green wavelength conversion member). The wavelength conversion sheet 250 further includes a blue light transmission layer 251B.

The red wavelength conversion layer 251R is provided at a position corresponding to the SEC1. In other words, the PIXR includes the red wavelength conversion layer 251R. The red wavelength conversion layer 251R includes a red QD (not illustrated) configured to emit red light (LR) as fluorescence by receiving the LB1 as excitation light. In other words, the red wavelength conversion layer 251R converts the LB1 into the LR. The red wavelength conversion layer 251R may be referred to as a red quantum dot light-emitting layer.

As described above, unlike the QD layer 15, the red wavelength conversion layer 251R emits light by photoluminescence (PL). The amount of light of the LR can be changed by adjusting the amount of light of the LB1, which is the excitation light. This similarly applies to the green wavelength conversion layer 251G described below. In the SEC1, the LR passing through a red CF 261R is emitted toward the display portion.

The green wavelength conversion layer 251G is provided at a position corresponding to the SEC2. In other words, the PIXG includes the green wavelength conversion layer 251G. The green wavelength conversion layer 251G includes a green QD (not illustrated) configured to emit green light (LG) as fluorescence by receiving the LB2 as excitation light. In other words, the green wavelength conversion layer 251G converts the LB2 into the LG. The green wavelength conversion layer 251G may be referred to as a green quantum dot light-emitting layer. In the SEC2, the LG passing through a green CF 261G is emitted toward the display portion.

The blue light transmission layer 251B is provided at a position corresponding to the SEC3. The blue light transmission layer 251B transmits the LB3. The material of the blue light transmission layer 251B is not particularly limited. The material is preferably a material having a particularly high light transmittance in at least the blue wavelength band (e.g., light-transmissive glass or resin). According to the above configuration, in the SEC3, the LB3 transmitted through the blue light transmission layer 251B is emitted toward the display portion.

In the present embodiment, a blue light transmission layer (hereinafter, a blue light transmission layer 261B) similar to the blue light transmission layer 251B is also provided in the CF sheet 260. The blue light transmission layer 261B is also provided at a position corresponding to the SEC3. The material of the blue light transmission layer 261B may be the same as or different from the material of the blue light transmission layer 251B. In the present embodiment, the LB3 transmitted through the blue light transmission layer 251B further passes through the blue light transmission layer 261B and is directed toward the display portion.

Note that the blue light transmission layer 261B of the CF sheet 260 may be provided with a blue CF. Alternatively, in a case where the CF sheet 260 is not provided, the blue CF may be provided in the blue light transmission layer 251B of the wavelength conversion sheet 250.

As described above, according to the light-emitting device 200, light in which the LR, the LG, and the LB3 are mixed (mixed light) can be supplied to the display portion. Accordingly, by appropriately adjusting each of the amounts of light of the LR, the LG, and the LB3, the desired tinge can be represented by the above-described mixed light.

The materials of the red QD and the green QD may be optionally selected. As described above, as an example, InP is suitably used as the non-Cd-based material. When InP is used, the fluorescence full-width at half-maximum can be made relatively narrow, and high luminous efficiency can be obtained.

As described in the first embodiment, by using the QD layer 15 as the blue light source, the half width of the blue light and the fluorescent peak wavelength can be controlled precisely compared with in the past. In other words, the monochromaticity of the blue light (LB3) in the PIXB can be improved. In view of this, in the light-emitting device 200, the wavelength conversion sheet 250 (more specifically, the red wavelength conversion layer 251R and the green wavelength conversion layer 251G) is provided as a red light source and a green light source.

According to the red wavelength conversion layer 251R, the monochromaticity of the red light (LR) in the PIXR can be improved. Similarly, according to the green wavelength conversion layer 251G, the monochromaticity of the green light (LG) in the PIXG can be improved. Thus, according to the light-emitting device 200, the display device 2000 having excellent display quality (color reproducibility, in particular) can be achieved.

However, the wavelength conversion sheet 250 cannot necessarily convert all of the LB (LB1 and LB2) received in the SEC1 and the SEC2 into light of a different wavelength. Specifically, the red wavelength conversion layer 251R cannot necessarily convert all of the LB1 into the LR. In other words, part of the LB1 is not absorbed in the red wavelength conversion layer 251R and passes through the red wavelength conversion layer 251R. Similarly, part of the LB2 is not absorbed in the green wavelength conversion layer 251G and passes through the green wavelength conversion layer 251G. Hereinafter, the LB1 passing through the red wavelength conversion layer 251R is referred to as a first residual blue light. The LB2 passing through the green wavelength conversion layer 251G is referred to as a second residual blue light.

Thus, in order to reduce the effect of the LB passing through the wavelength conversion sheet 250 in the SEC1 and SEC2 (the first residual blue light and the second residual blue light), the CF sheet 260 is provided at a position corresponding to the wavelength conversion sheet 250. The CF sheet 260 is provided below the wavelength conversion sheet 250. In other words, the CF sheet 260 is provided to cover the wavelength conversion sheet 250 when viewed from the display surface. The CF sheet 260 includes the red CF 261R and the green CF 261G. As described above, the CF sheet 260 further includes the blue light transmission layer 261B.

In order to reduce the effect of the first residual blue light in the PIXR, the red CF 261R is provided at a position corresponding to the SEC1 (a position corresponding to the red wavelength conversion layer 251R). Similarly, in order to reduce the effect of the second residual blue light in the PIXG, the green CF 261G is provided at a position corresponding to the SEC2 (a position corresponding to the green wavelength conversion layer 251G).

The red CF 261R and the green CF 261G selectively transmit red light and green light, respectively. Specifically, the red CF 261R has a high light transmittance in the red wavelength band and a relatively low light transmittance in other wavelength bands. The green CF 261G has a high light transmittance in the green wavelength band and a relatively low light transmittance in other wavelength bands. In the second embodiment, it is preferable that both of the red CF 261R and the green CF 261G have a particularly low light transmittance in the blue wavelength band.

By providing the CF sheet 260, the first residual blue light directed toward the display portion can be blocked by the red CF 261R. Similarly, the second residual blue light directed toward the display portion can be blocked by the green CF 261G. As a result, the monochromaticity of each of the LR and the LG in the display portion can be further improved. Thus, the display quality of the display device 2000 can be further enhanced. However, depending on the display quality required for the display device 2000, the CF sheet 260 can be omitted.

The wavelength conversion sheet 250 and the CF sheet 260 may be formed integrally. For example, by forming the CF sheet 260 on the upper face of the wavelength conversion sheet 250 at the positions corresponding to the SEC1 to SEC3, an integral sheet (hereinafter, referred to as a “wavelength conversion/CF sheet”) may be manufactured. The wavelength conversion/CF sheet may be disposed below the light-emitting element 2 such that the CF sheet 260 side of the wavelength conversion/CF sheet faces the display surface.

As another example, by forming the wavelength conversion sheet 250 on the upper face of the CF sheet 260 at the positions corresponding to the SEC1 to SEC3, the wavelength conversion/CF sheet may be manufactured.

As yet another example, the wavelength conversion/CF sheet may be manufactured by forming the red wavelength conversion layer 251R and the green wavelength conversion layer 251G on the upper face of the CF sheet 260 at the respective positions corresponding to the SEC1 and SEC2. As described above, the wavelength conversion sheet may be provided only at positions corresponding to the SEC1 and the SEC2. In this case, the formation of the blue light transmission layer 251B can be omitted.

### Supplement

When the film thickness of the wavelength conversion sheet 250 (more specifically, the layer thickness of each of the red wavelength conversion layer 251R and the green wavelength conversion layer 251G; hereinafter, “Dt”) is too small (e.g., less than 0.1 μm), the absorption of the LB in the wavelength conversion sheet 250 is insufficient. As a result, the wavelength conversion efficiency of the wavelength conversion sheet 250 decreases. On the other hand, when the Dt is too large (e.g., when the Dt exceeds 100 μm), the light extraction efficiency in the wavelength conversion sheet 250 decreases. The decrease in the light extraction efficiency is due to, for example, the fluorescence (LR and LG) generated in the wavelength conversion sheet 250 being scattered by the wavelength conversion sheet 250 itself.

As described above, from the perspective of improving the efficiency of the light-emitting device 200, the Dt is preferably 0.1 μm to 100 μm. In order to further improve the efficiency, the Dt is particularly preferably 5 μm to 50 μm. As an example, the Dt can be set to a desired value by forming the wavelength conversion sheet 250 by using a binder.

The material of the binder can be freely selected, but an acrylic resin is preferably used as the material. This is because the acrylic resin has high transparency and can effectively disperse the QDs.

### Modified Example

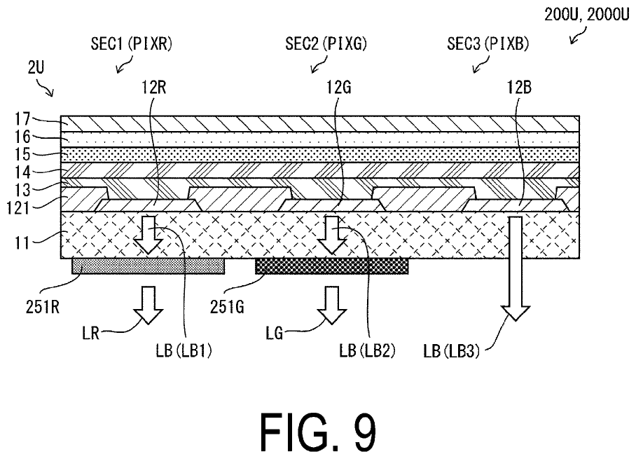

FIG. 9 is a diagram for explaining a modified example of the display device 2000 (hereinafter, a display device 2000U). A light-emitting device and a light-emitting element (electroluminescent element) of the display device 2000U are referred to as a light-emitting device 200U and a light-emitting element 2U, respectively. For simplicity of illustration, some of the members illustrated in FIG. 8 are not illustrated in FIG. 9.

In the display device 2000U, a first electrode (e.g., an anode electrode) is provided individually for the PIXR, the PIXG, and the PIXB. Hereinafter, (i) a first electrode provided on the PIXR is referred to as a red first electrode 12R, (ii) a first electrode provided on the PIXG is referred to as a green first electrode 12G, and (iii) a first electrode provided on the PIXB is referred to as a blue first electrode 12B. In the example illustrated in FIG. 9, an edge cover 121 is provided at each end portion of the red first electrode 12R, the green first electrode 12G, and the blue first electrode 12B.

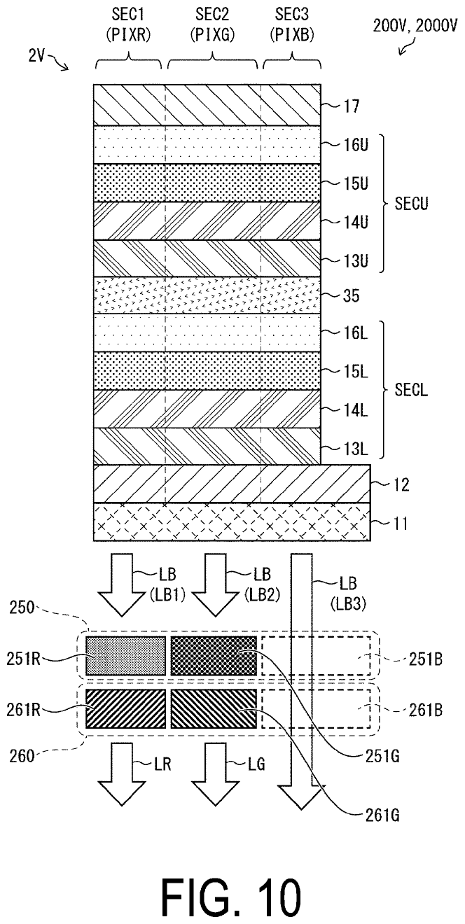

In the display device 2000U, the QD layer 15 is interposed between (i) the red first electrode 12R, the green first electrode 12G, and the blue first electrode 12B and (ii) the cathode electrode 17 (a second electrode). Additionally, the QD layer 15 is shared by the PIXR, the PIXG, and the PIXB. The cathode electrode 17 (the second electrode) is also shared by the PIXR, the PIXG, and the PIXB. This similarly applies to other layers. The display device 2000U can be said to be one specific example of the configuration of the display device 2000. The configuration illustrated in FIG. 9 is also applicable to the configurations of FIG. 10 to FIG. 12 described below.

### Modified Example

FIG. 10 is a diagram for explaining another modified example of the display device 2000 (hereinafter, a display device 2000V). A light-emitting device and a light-emitting element (electroluminescent element) of the display device 2000V are referred to as a light-emitting device 200V and a light-emitting element 2V, respectively. The light-emitting element 2V is a tandem type electroluminescent element configured based on the light-emitting element 2.

Specifically, unlike the light-emitting element 2, the light-emitting element 2V includes a lower light-emitting unit (SECL) and an upper light-emitting unit (SECU) as a pair of light-emitting units. The SECL is formed on an upper face of the anode electrode 12. On the other hand, the SECU is formed on a lower face of the cathode electrode 17. Each of the SECL and the SECU includes layers similar to the hole injection layer 13 to the electron transport layer 16 of the light-emitting element 2. In the example illustrated in FIG. 10, the layers of the SECL are referred to as a hole injection layer 13L to an electron transport layer 16L, and the layers of the SECU are referred to as a hole injection layer 13U to an electron transport layer 16U. In the light-emitting element 2V, a charge generating layer 35 is further provided between the SECL and the SECU.

An example of a method for manufacturing the light-emitting element 2V is as follows. First, after film formation of the anode electrode 12, the SECL (the hole injection layer 13L to the electron transport layer 16L) is formed on the upper face of the anode electrode 12 by similar techniques to those in the first embodiment. Then, the charge generating layer 35 is formed on the upper face of the electron transport layer 16L. Subsequently, the SECU (the hole injection layer 13U to the electron transport layer 16U) is formed on the upper face of the charge generating layer 35. Finally, the cathode electrode 17 is formed on the upper face of the electron transport layer 16U.

In the light-emitting element 2V, two QD layers (QD layers 15L and 15U) are provided as blue light sources. Thus, according to the light-emitting element 2V, the amount of light of the LB can be increased as compared with the light-emitting element 2. Thus, the amounts of light of the LR and the LG may also be increased as compared with those of the light-emitting element 2.

As described above, according to the light-emitting element 2V, the light emission intensity of the light-emitting device 200V can be increased as compared with the light-emitting device 200. Thus, the viewability of the image displayed on the display device 2000V can be increased as compared with the display device 2000. In other words, the display device 2000V having more excellent display quality can be achieved.

The charge generating layer 35 of the light-emitting element 2V is provided as a buffer layer between the electron transport layer 16L and the hole injection layer 13U. By providing the charge generating layer 35, the efficiency of recombination of the positive holes and the electrons in the QD layers 15L and 15U can be improved. In other words, the amount of light of the LB can be increased more effectively. However, depending on the display quality required for the display device 2000V, the charge generating layer 35 can be omitted.

### Third Embodiment

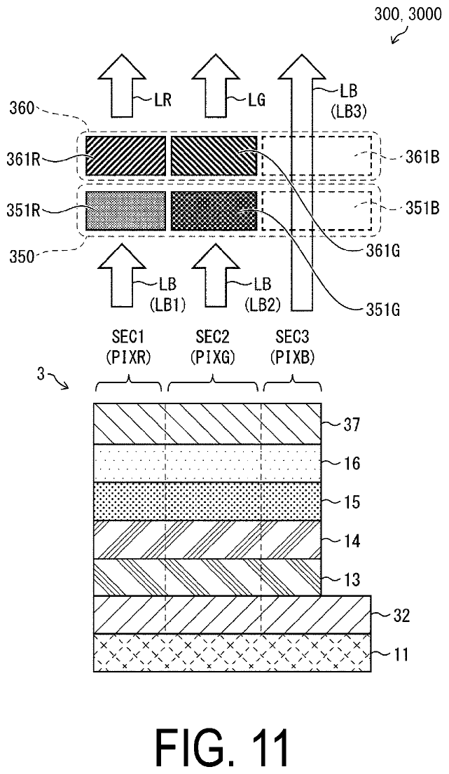

FIG. 11 is a diagram for explaining a display device 3000 according to a third embodiment. A light-emitting device and a light-emitting element (electroluminescent element) of the display device 3000 are referred to as a light-emitting device 300 and a light-emitting element 3, respectively. The light-emitting element 3 has a configuration generally similar to that of the light-emitting element 2. However, unlike the light-emitting element 2, the light-emitting element 3 is a TE type electroluminescent element. In the example illustrated in FIG. 11, a display portion (not illustrated) of the display device 3000 is provided above the light-emitting element 3.

Specifically, unlike the anode electrode 12, an anode electrode (hereinafter, an anode electrode 32) (first electrode) of the light-emitting element 3 is formed as a light-reflective electrode (an electrode similar to the cathode electrode 17). In contrast, unlike the cathode electrode 17, a cathode electrode (hereinafter, a cathode electrode 37) (second electrode) of the light-emitting element 3 is formed as a light-transmissive electrode (an electrode similar to the anode electrode 12). By providing the anode electrode 32 and the cathode electrode 37 in this way, the TE type light-emitting element 3 can be configured. In the light-emitting element 3, a poorly light-transmissive substrate (for example, a plastic substrate) may be used as the substrate 11.

A wavelength conversion sheet 350 and a CF sheet 360 illustrated in FIG. 11 are a wavelength conversion sheet and a CF sheet, respectively, of the light-emitting device 300. A red wavelength conversion layer 351R is a red wavelength conversion layer of the wavelength conversion sheet 350, and a green wavelength conversion layer 351G is a green wavelength conversion layer of the wavelength conversion sheet 350. A blue light transmission layer 351B is a blue light transmission layer of the wavelength conversion sheet 350. A red CF 361R is a red CF of the CF sheet 360, and a green CF 361G is a green CF of the CF sheet 360. A blue light transmission layer 361B is a blue light transmission layer of the CF sheet 360.

In the light-emitting device 300, since the light-emitting element 3 is the TE type, the wavelength conversion sheet 350 and the CF sheet 360 are disposed above the light-emitting element 3. The third embodiment also provides similar effects to those of the second embodiment. In addition, as described above, according to the light-emitting element 3, the EQE may be improved as compared with the light-emitting element 2 (BE type electroluminescent element).

### Modified Example

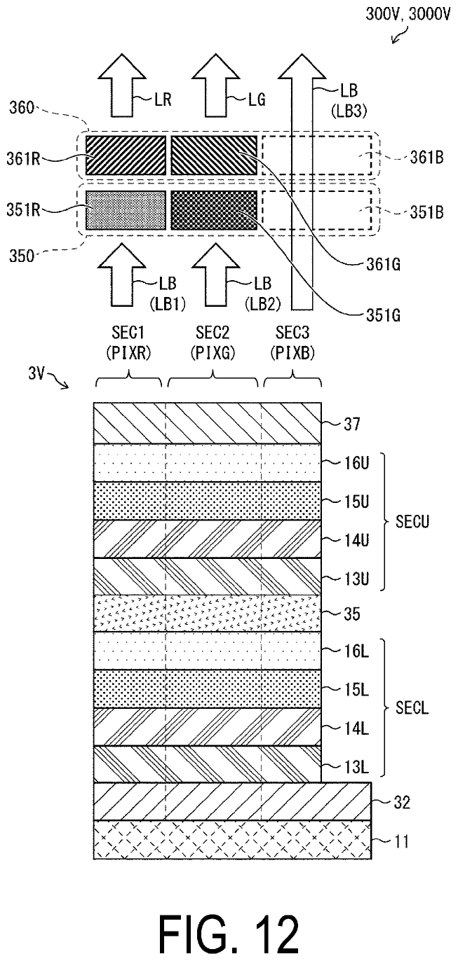

FIG. 12 is a diagram for explaining a modified example of the display device 3000 (hereinafter, a display device 3000V). A light-emitting device and a light-emitting element (electroluminescent element) of the display device 3000V are referred to as a light-emitting device 300V and a light-emitting element 3V, respectively. The light-emitting element 3V is a tandem type electroluminescent element configured based on the light-emitting element 3. As discussed above, the tandem structure may also be adopted in a TE type electroluminescent element in a similar manner to that in the example (the light-emitting element 2V) illustrated in FIG. 10.

In the display device described above, by using the non-Cd-based materials for the red QD (red quantum dot), the green QD (green quantum dot), and the blue QD (blue quantum dot), an effect of being possible to provide an environment-friendly display device is exhibited.

The disclosure is not limited to the embodiments described above, and various modifications may be made within the scope of the claims. Embodiments obtained by appropriately combining technical approaches disclosed in the different embodiments also fall within the technical scope of the disclosure. Moreover, novel technical features may be formed by combining the technical approaches stated in each of the embodiments.

### REFERENCE SIGNS LIST

1, 2, 2U, 2V, 3, 3V Light-emitting element (electroluminescent element)
12, 32 Anode electrode (anode, first electrode)
12B Blue first electrode (anode electrode)
12R Red first electrode (anode electrode)
12G Green first electrode 12G (anode electrode)
13, 13L, 13U Hole injection layer
14 Hole transport layer
15, 15L, 15U QD layer (quantum dot light-emitting layer)
16, 16L, 16U Electron transport layer
17, 37 Cathode electrode
21 QD (quantum dot)
22 Core
23 Shell
23a Innermost layer
23b Outermost layer
24 Boundary portion
25 Outermost portion
27a First layer (innermost layer)
27e Fifth layer (outermost layer)

1. A quantum dot containing no cadmium (Cd) and configured to emit blue light, the quantum dot comprising:
a core; and
a shell provided on a surface of the core,
wherein the core at least contains Zn and Se, and
the shell
has a thickness in a range from 0.5 nm to 3 nm,
contains Zn, Se, and S in a boundary portion adjacent to the core, and
contains Zn and S in an outermost portion.

2. The quantum dot according to claim 1,
wherein a particle size of the core falls within a range from 3 nm to 20 nm.

3. The quantum dot according to claim 1,
wherein in a case that a composition ratio of Zn:Se:S in the shell is set to 1:1-x:x, a relation of 0.2≤x≤0.8 is satisfied in the boundary portion, and a relation of x=1 is satisfied in the outermost portion.

4. The quantum dot according to claim 1,
wherein a composition of the shell changes in such a manner that a composition ratio of Se in relation to Zn stepwisely decreases and a composition ratio of S in relation to Zn stepwisely increases from the boundary portion toward the outermost portion.

5. The quantum dot according to claim 1,
wherein the shell has a layered structure in which a plurality of layers is layered,
a total thickness of the plurality of layers falls within a range from 0.5 nm to 3 nm, and
among the plurality of layers, an innermost layer adjacent to the core contains Zn, Se and S, and an outermost layer contains Zn and S.

6. The quantum dot according to claim 5,
wherein the number of layers of the shell is five or less.

7. The quantum dot according to claim 6,
wherein a layer thickness of each layer of the shell is 20% or more of the total thickness of the shell.

8. The quantum dot according to claim 5,
wherein the shell has a dual-layer structure of the innermost layer and the outermost layer, and
a layer thickness of the innermost layer is 20% or more and 80% or less of the total thickness of the shell.

9. The quantum dot according to claim 5,
wherein the shell has a dual-layer structure of the innermost layer and the outermost layer, and
in a case that a composition ratio of Zn:Se:S in the shell is set to 1:1-x:x, a relation of 0.2≤x<0.8 is satisfied in the innermost layer, and a relation of x=1 is satisfied in the outermost layer.

10. The quantum dot according to claim 5,
wherein the shell includes three or more layers, and
a composition of the shell changes in such a manner that a percentage content of Se stepwisely decreases and a percentage content of S stepwisely increases from the innermost layer toward the outermost layer.

11. The quantum dot according to claim 1,
wherein, of the core and the shell, at least the core further contains Cu, and
a content of Cu in relation to Zn in the quantum dot is in a range from 0.1 ppm to 10 ppm.

12. A quantum dot containing no Cd, configured to emit blue light, and used in an electroluminescent element for a display device, the quantum dot comprising:
a core; and
a shell covering the core,
wherein the core at least contains Zn and Se,
a film thickness of the shell falls within a range from 0.5 nm to 3 nm, and
in a case that
an operation voltage of the electroluminescent element at a luminance of 5 cd/m² is taken as Vmin,
in a case where a maximum operation voltage set as the electroluminescent element is lower than 8 V, the maximum operation voltage is taken as Vmax, and
in a case where the maximum operation voltage is higher than or equal to 8 V, 8 Vis taken as Vmax,
a variation in a light emission peak wavelength is smaller than or equal to 1 nm at the operation voltage in a range from the Vmin to the Vmax.

13. An electroluminescent element, comprising:
an anode electrode;
a cathode electrode; and
a light-emitting layer provided between the anode electrode and the cathode electrode,
wherein the light-emitting layer is a quantum dot light-emitting layer including the quantum dot according to claim 1.

14. The electroluminescent element according to claim 13, further comprising:
an electron transport layer between the cathode electrode and the light-emitting layer,
wherein the electron transport layer contains ZnO.
